(19) United States
(12) Patent Application Publication
(10) Pub. No.: US 2025/0118609 A1
(43) Pub. Date: Apr. 10, 2025

(54) Semiconductor Packages and Methods of Forming

(71) Applicant: Taiwan Semiconductor Manufacturing Co., Ltd., Hsinchu (TW)

(72) Inventors: Hsin Chang, Hsinchu (TW); Po-Han Wang, Hsinchu (TW); Yu-Hsiang Hu, Hsinchu (TW); Hung-Jui Kuo, Hsinchu (TW)

(21) Appl. No.: 18/410,301

(22) Filed: Jan. 11, 2024

Related U.S. Application Data
(60) Provisional application No. 63/589,042, filed on Oct. 10, 2023.

(51) Int. Cl. H01L 23/31; H01L 23/00; H01L 23/498; H01L 23/522; H01L 25/00; H01L 25/065

(52) U.S. Cl. CPC H01L 23/3128; H01L 23/49816; H01L 23/49822; H01L 23/5226; H01L 24/32; H01L 24/48; H01L 24/73; H01L 24/94; H01L 25/0652; H01L 25/50; H01L 2224/32225; H01L 2224/48229; H01L 2224/73215; H01L 2224/94; H01L 2924/181

(57) ABSTRACT

A method of forming a semiconductor package includes: surrounding a die with a molding material; and forming a redistribution structure (RDS) over the molding material and electrically coupled to the die, which includes: depositing a first dielectric layer over the molding material; patterning the first dielectric layer to form first openings in the first dielectric layer; performing a first descum process to clean the first openings; after performing the first descum process, forming a first redistribution layer (RDL) on the first dielectric layer; depositing a second dielectric layer over the molding material; patterning the second dielectric layer to form second openings in the second dielectric layer; performing a second descum process to clean the second openings, where the first and second descum processes are performed under different process conditions; and after performing the second descum process, forming a second RDL on the second dielectric layer.

### PRIORITY CLAIM

This application claims the benefit of U.S. Provisional Application No. 63/589,042, filed on Oct. 10, 2023 and entitled “Advanced InFO POP PM processes,” which application is hereby incorporated herein by reference.

### BACKGROUND

The semiconductor industry has experienced rapid growth due to ongoing improvements in the integration density of a variety of electronic components (e.g., transistors, diodes, resistors, capacitors, etc.). For the most part, improvement in integration density has resulted from iterative reduction of minimum feature size, which allows more components to be integrated into a given area. As the demand for shrinking electronic devices has grown, a need for smaller and more creative packaging techniques of semiconductor dies has emerged. An example of such packaging systems is Package-on-Package (POP) technology. In a POP device, a top semiconductor package is stacked on top of a bottom semiconductor package to provide a high level of integration and component density. PoP technology generally enables production of semiconductor devices with enhanced functionalities and small footprints on a printed circuit board (PCB).

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-9, 10A, 10B, 11, 12A, 12B, 13, 14A, 14B, and 15-24 illustrate cross-sectional views of a semiconductor package at various manufacturing steps, in accordance with an embodiment.

FIGS. 25A and 25B together illustrate a flow chart of a method for forming a semiconductor package, in accordance with an embodiment.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. Throughout the discussion herein, unless otherwise specified, the same or similar reference numerals in different figures refer to the same or similar component formed by a same or similar process using the same or similar material(s).

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Embodiments discussed herein may be discussed in a specific context, e.g., formation of the redistribution structure of an integrated fan-out (InFO) package. The redistribution structure of the InFO package includes a plurality of polymer layers and redistribution layers (e.g., metal patterns that includes conductive lines and vias) formed over the polymer layers. Depending on the topology of the underlying metallization patterns, each of the polymer layers in the redistribution structure may be treated by a different descum process. For example, a point-of-reference (POR) descum process may be performed at about 70 pascals for a duration of about 60 seconds, and an enhanced low-pressure descum process is performed at a lower pressure and for a longer duration, such as at about 35 pascals and for a duration between 60 seconds and 300 second. A criteria is disclosed for determining which descum process to use for each polymer layer. The enhanced lower-pressure descum process results in higher surface roughness and lower reflectivity for the polymer layer treated, which alleviate the bridging issue (e.g., electrical short) for the metallization patterns formed on the treated polymer layer. In addition, better sidewall profile and smaller footing are achieved by the enhanced low-pressure descum process, which in turn allow for better overlay control and less stress related issues (e.g., delamination and cracking). The disclosed criteria allows flexible choice between the POR descum process and the enhanced low-pressure descum process to achieve balance between better device performance and higher production throughput.

It should be noted that embodiments discussed herein may not necessarily illustrate every component or feature that may be present in a structure. Further, the method embodiment discussed herein may be discussed as being performed in a particular order; however, other method embodiments may be performed in any logical order.

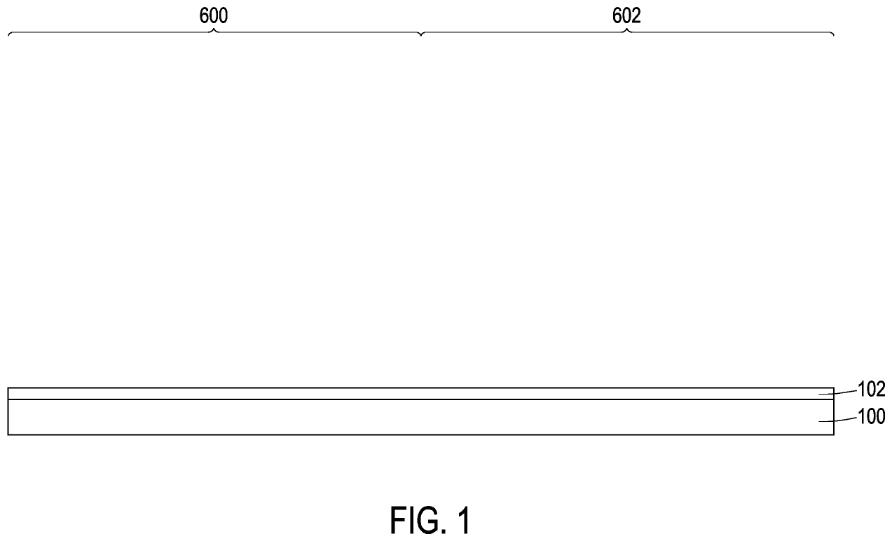

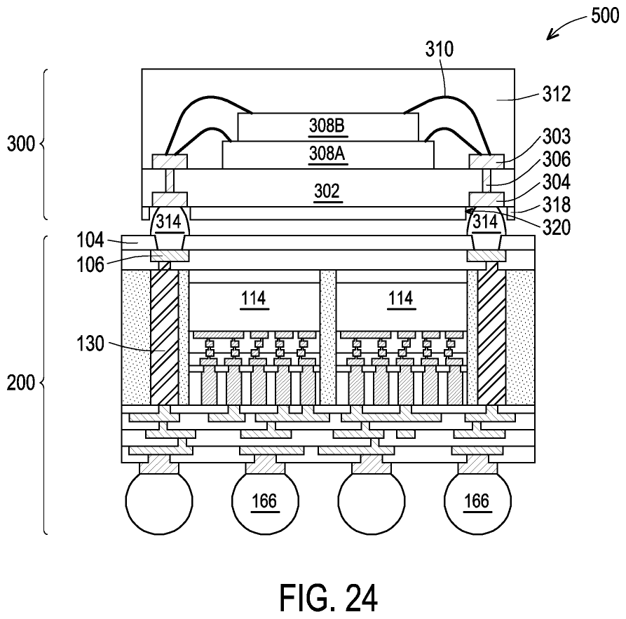

FIGS. 1-9, 10A, 10B, 11, 12A, 12B, 13, 14A, 14B, and 15-24 illustrate cross-sectional views of a semiconductor package 500 at various manufacturing steps, in accordance with an embodiment. The semiconductor package 500 is a POP package formed by attaching a top package 300 (e.g., a memory package, see FIG. 24) to a bottom package 200 (e.g., an integrated fan-out (InFO) package), in an embodiment. In the illustrate embodiment, FIGS. 1-9, 10A, 10B, 11, 12A, 12B, 13, 14A, 14B, and 15-23 illustrate processing steps to form an InFO package 200 as the bottom package. FIG. 24 illustrates formation of the POP package 500 by attaching the top package 300 to the InFO package 200.

Referring now to FIG. 1, which illustrates a carrier substrate 100 and a release layer 102 formed on the carrier substrate 100. A first package region 600 and a second package region 602 for the formation of a first semiconductor package (e.g., a first InFO package) and a second semiconductor package (e.g., a second InFO package), respectively, are illustrated.

The carrier substrate 100 may be a glass carrier substrate, a ceramic carrier substrate, or the like. The carrier substrate 100 may be a wafer, such that multiple packages can be formed on the carrier substrate 100 simultaneously. The release layer 102 may be formed of a polymer-based material, which may be removed along with the carrier substrate 100 from the overlying structures that will be formed in subsequent steps. In some embodiments, the release layer 102 is an epoxy-based thermal-release material, which loses its adhesive property when heated, such as a light-to-heat-conversion (LTHC) release coating. In other embodiments, the release layer 102 may be an ultra-violet (UV) glue, which loses its adhesive property when exposed to UV lights. The release layer 102 may be dispensed as a liquid and cured, may be a laminate film laminated onto the carrier substrate 100, or may be the like. The top surface of the release layer 102 may be leveled and may have a high degree of planarity (e.g., flatness).

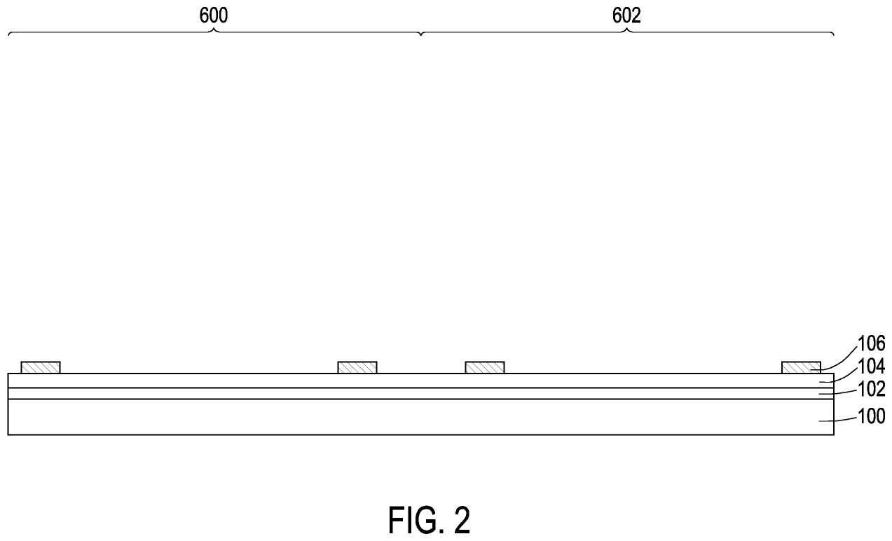

In FIG. 2, a dielectric layer 104 and metallization patterns 106 (sometimes referred to as a redistribution layer 106 or redistribution lines 106) are formed. As illustrated in FIG. 2, the dielectric layer 104 is formed on the release layer 102. The bottom surface of the dielectric layer 104 may be in contact with the top surface of the release layer 102. In some embodiments, the dielectric layer 104 is formed of a polymer, such as polybenzoxazole (PBO), polyimide, benzocyclobutene (BCB), or the like. In other embodiments, the dielectric layer 104 is formed of a nitride such as silicon nitride; an oxide such as silicon oxide, phosphosilicate glass (PSG), borosilicate glass (BSG), boron-doped phosphosilicate glass (BPSG), or the like; or the like. The dielectric layer 104 may be formed by any acceptable deposition process, such as spin coating, chemical vapor deposition (CVD), laminating, the like, or a combination thereof.

The metallization patterns 106 are formed on the dielectric layer 104. As an example to form the metallization patterns 106, a seed layer (not shown) is formed over the dielectric layer 104. In some embodiments, the seed layer is a metal layer, which may be a single layer or a composite layer comprising a plurality of sub-layers formed of different materials. In some embodiments, the seed layer comprises a titanium layer and a copper layer over the titanium layer. The seed layer may be formed using, for example, physical vapor deposition (PVD) or the like. A photoresist is then formed and patterned on the seed layer. The photoresist may be formed by spin coating or the like and may be exposed to light for patterning. The patterns of the photoresist correspond to the metallization patterns 106. The patterning of the photoresist forms openings through the photoresist to expose the seed layer. A conductive material is formed in the openings of the photoresist and on the exposed portions of the seed layer. The conductive material may be formed by plating, such as electroplating or electroless plating, or the like. The conductive material may comprise a metal, like copper, titanium, tungsten, aluminum, or the like. Then, the photoresist and portions of the seed layer on which the conductive material is not formed are removed. The photoresist may be removed by an acceptable ashing or stripping process, such as using an oxygen plasma or the like. Once the photoresist is removed, exposed portions of the seed layer are removed, such as by using an acceptable etching process, such as by wet or dry etching. The remaining portions of the seed layer and conductive material form the metallization patterns 106. Note that in the discussion herein, unless otherwise specified, “conductive” means “electrically conductive,” and a conductive material refers to an electrically conductive material (e.g., having low electrical resistance and suitable for transmitting electrical current), such as copper, tungsten, aluminum, gold, the like, or combinations thereof. The term “conductive” may be used interchangeably with the term “electrically conductive” herein.

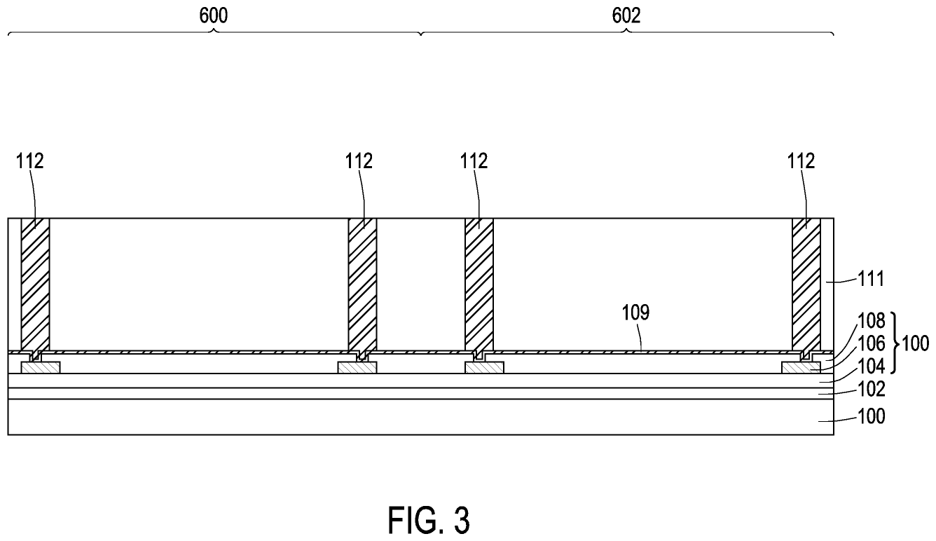

Next, in FIG. 3, a dielectric layer 108 is formed on the metallization patterns 106 and the dielectric layer 104. In some embodiments, the dielectric layer 108 is formed of a polymer, which may be a photo-sensitive material such as PBO, polyimide, BCB, or the like, that may be patterned using a lithography mask. In other embodiments, the dielectric layer 108 is formed of a nitride such as silicon nitride; an oxide such as silicon oxide, PSG, BSG, BPSG; or the like. The dielectric layer 108 may be formed by spin coating, lamination, CVD, the like, or a combination thereof. The dielectric layer 108 is then patterned to form openings to expose portions of the metallization patterns 106. The patterning may be by an acceptable process, such as by exposing the dielectric layer 108 to light when the dielectric layer is a photo-sensitive material or by etching using, for example, an anisotropic etch.

The dielectric layers 104 and 108 and the metallization patterns 106 may be referred to as a back-side redistribution structure 110. As illustrated, the back-side redistribution structure 110 includes the two dielectric layers 104 and 108 and one layer of metallization patterns 106. In other embodiments, the back-side redistribution structure 110 can include any number of dielectric layers, metallization patterns, and vias. One or more additional metallization pattern and dielectric layer may be formed in the back-side redistribution structure 110 by repeating the processes for forming the metallization patterns 106 and dielectric layer 108. Vias may be formed during the formation of a metallization pattern by forming the seed layer and conductive material of the metallization pattern in the opening of the underlying dielectric layer. The vias may therefore interconnect and electrically couple the various metallization patterns.

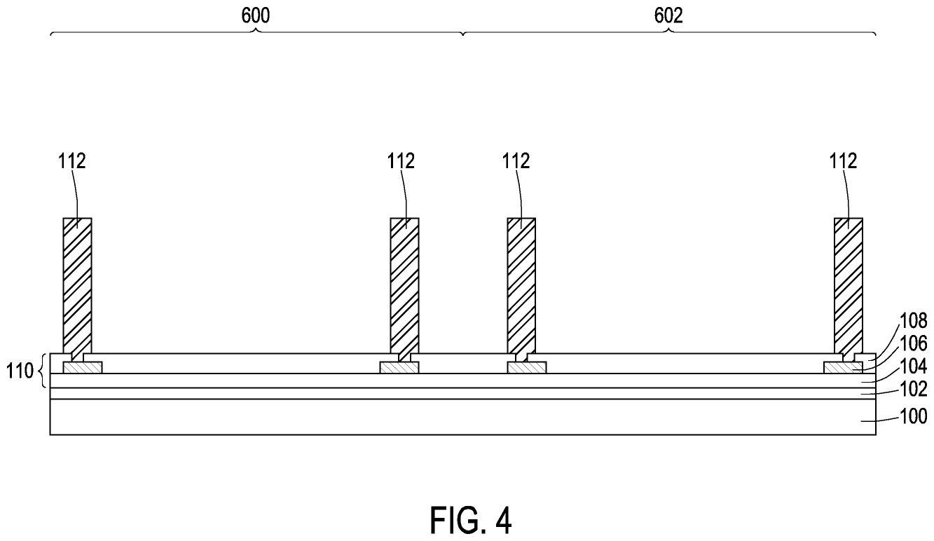

Next, in FIGS. 3 and 4, through vias 112 are formed. In an embodiment, to form the through vias 112, openings are formed in the dielectric layer 108 to expose portions of the underlying metallization patterns 106. A seed layer 109 is formed over the dielectric layer 108 and in the opening over the exposed portions of the metallization patterns 106 as illustrated. In some embodiments, the seed layer 109 is a metal layer, which may be a single layer or a composite layer comprising a plurality of sub-layers formed of different materials. In some embodiments, the seed layer 109 comprises a titanium layer and a copper layer over the titanium layer. The seed layer 109 may be formed using, for example, PVD or the like. Next, a photoresist 111 is formed and patterned on the seed layer 109. The photoresist 111 may be formed by spin coating or the like and may be exposed to light for patterning. The pattern of the photoresist 111 corresponds to the through vias. The patterning forms openings through the photoresist 111 to expose the seed layer 109. A conductive material is formed in the openings of the photoresist 111 and on the exposed portions of the seed layer 109. The conductive material may be formed by plating, such as electroplating or electroless plating, or the like. The conductive material may comprise a metal, like copper, titanium, tungsten, aluminum, or the like.

Next, in FIG. 4, the photoresist 111 and portions of the seed layer 109 on which the conductive material is not formed are removed. The photoresist 111 may be removed by an acceptable ashing or stripping process, such as using an oxygen plasma or the like. Once the photoresist 111 is removed, exposed portions of the seed layer 109 are removed, such as by using an acceptable etching process, such as by wet or dry etching. The remaining portions of the seed layer 109 and conductive material form through vias 112. Note that for simplicity, portions of the seed layer 109 underlying the through vias 112 are not separately illustrated in FIG. 4 and subsequent figures.

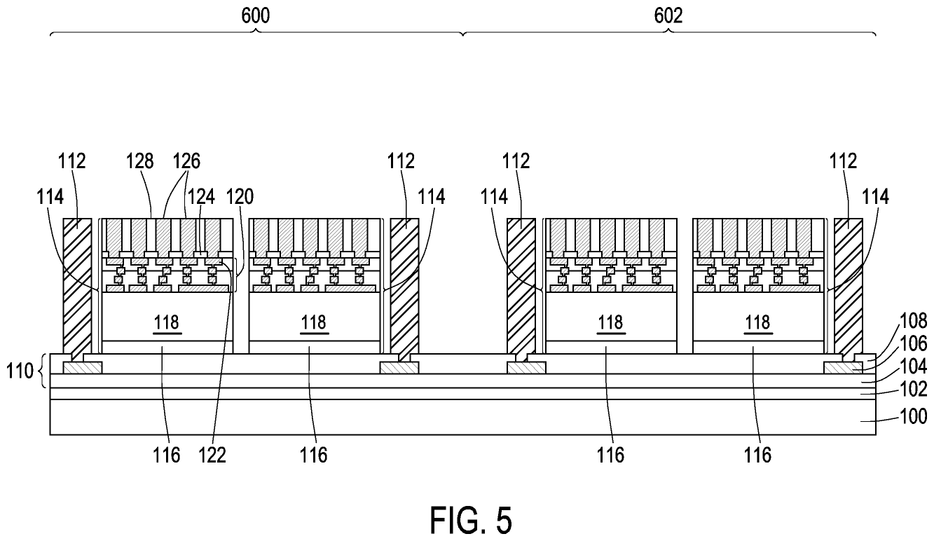

Next, in FIG. 5, integrated circuit dies 114 (also referred to as dies 114) are adhered to the dielectric layer 108 by an adhesive 116. As illustrated in FIG. 5, two integrated circuit dies 114 are adhered in each of the first package region 600 and the second package region 602. In other embodiments, more or less integrated circuit dies 114 may be adhered in each region. For example, in an embodiment, only one integrated circuit die 114 may be adhered in each region. The integrated circuit dies 114 may be logic dies (e.g., central processing unit, microcontroller, etc.), memory dies (e.g., dynamic random access memory (DRAM) die, static random access memory (SRAM) die, etc.), power management dies (e.g., power management integrated circuit (PMIC) die), radio frequency (RF) dies, sensor dies, micro-electro-mechanical-system (MEMS) dies, signal processing dies (e.g., digital signal processing (DSP) die), front-end dies (e.g., analog front-end (AFE) dies), the like, or a combination thereof. Also, in some embodiments, the integrated circuit dies 114 may be different sizes (e.g., different heights and/or surface areas), and in other embodiments, the integrated circuit dies 114 may be the same size (e.g., same heights and/or surface areas).

Before being adhered to the dielectric layer 108, the integrated circuit dies 114 may be processed according to applicable manufacturing processes to form integrated circuits in the integrated circuit dies 114. For example, the integrated circuit dies 114 each include a semiconductor substrate 118, such as silicon, doped or undoped, or an active layer of a semiconductor-on-insulator (SOI) substrate. The semiconductor substrate may include other semiconductor materials, such as germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. Other substrates, such as multi-layered or gradient substrates, may also be used. Devices, such as transistors, diodes, capacitors, resistors, etc., may be formed in and/or on the semiconductor substrate 118 and may be interconnected by interconnect structures 120 formed by, for example, metallization patterns in one or more dielectric layers on the semiconductor substrate 118 to form an integrated circuit.

The integrated circuit dies 114 further comprise pads 122, such as aluminum pads, to which external connections are made. The pads 122 are on what may be referred to as respective active sides of the integrated circuit dies 114. Passivation films 124 are on the integrated circuit dies 114 and on portions of the pads 122. Openings are through the passivation films 124 to the pads 122. Die connectors 126, such as conductive pillars (for example, comprising a metal such as copper), are in the openings through the passivation films 124 and are mechanically and electrically coupled to the respective pads 122. The die connectors 126 may be formed by, for example, plating, or the like. The die connectors 126 are electrically coupled to the circuits of the integrated circuit dies 114.

A dielectric material 128 is on the active sides of the integrated circuit dies 114, such as on the passivation films 124 and the die connectors 126. The dielectric material 128 laterally encapsulates the die connectors 126, and the dielectric material 128 is laterally coterminous with the respective integrated circuit dies 114. The dielectric material 128 may be a polymer such as PBO, polyimide, BCB, or the like; a nitride such as silicon nitride or the like; an oxide such as silicon oxide, PSG, BSG, BPSG, or the like; the like, or a combination thereof, and may be formed, for example, by spin coating, lamination, CVD, or the like.

Adhesive 116 is on back-sides of the integrated circuit dies 114 and adheres the integrated circuit dies 114 to the back-side redistribution structure 110, such as the dielectric layer 108 in the illustration. The adhesive 116 may be any suitable adhesive, epoxy, die attach film (DAF), or the like. The adhesive 116 may be applied to a back-side of the integrated circuit dies 114, such as to a back-side of the respective semiconductor wafer or may be applied over the surface of the carrier substrate 100. The integrated circuit dies 114 may be singulated, such as by sawing or dicing, and adhered to the dielectric layer 108 by the adhesive 116 using, for example, a pick-and-place tool.

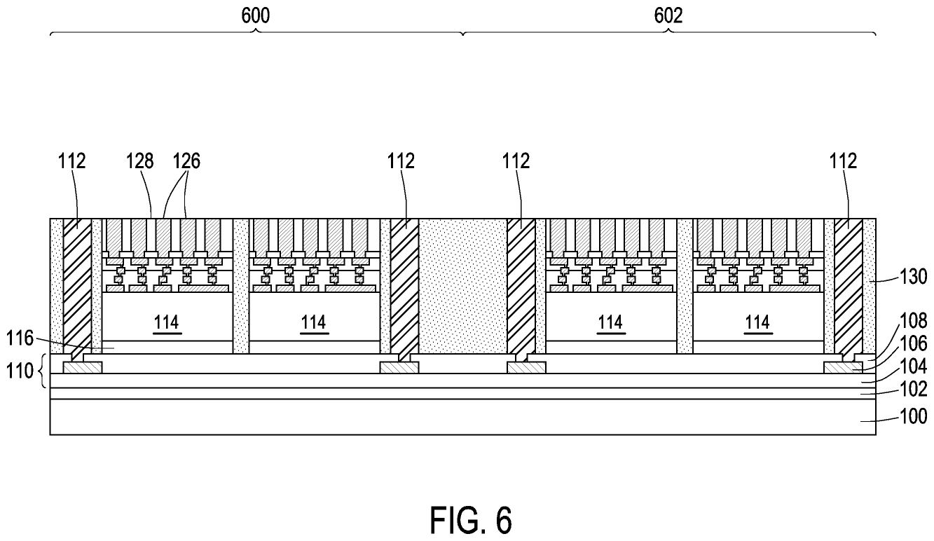

Next, in FIG. 6, an encapsulant 130 (may also be referred to as a molding material 130) is formed on the various components. The encapsulant 130 may be a molding compound, epoxy, or the like, and may be applied by compression molding, transfer molding, or the like. After curing, the encapsulant 130 may undergo a planarization process, such as a grinding process, a chemical mechanical planarization (CMP) process, or the like, to expose the through vias 112 and die connectors 126. Top surfaces of the through vias 112, die connectors 126, and encapsulant 130 are coplanar after the planarization process.

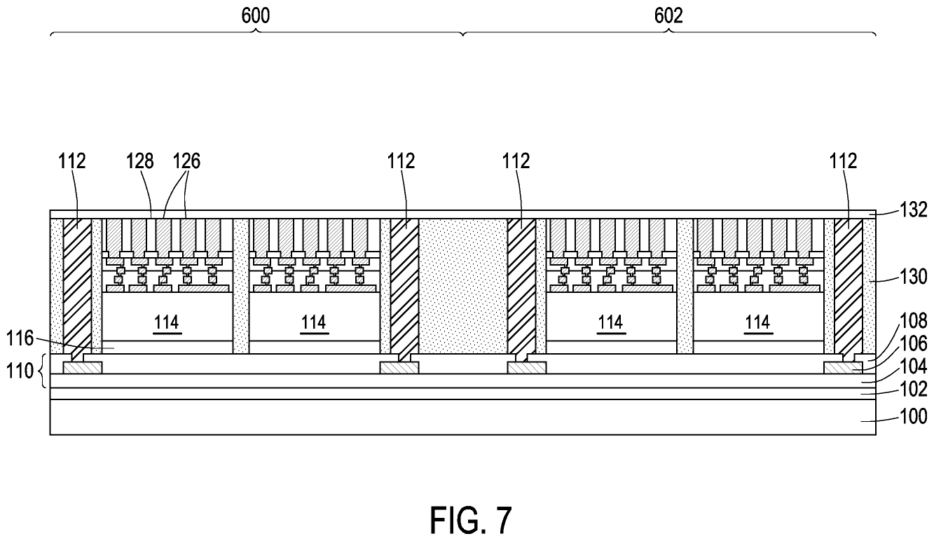

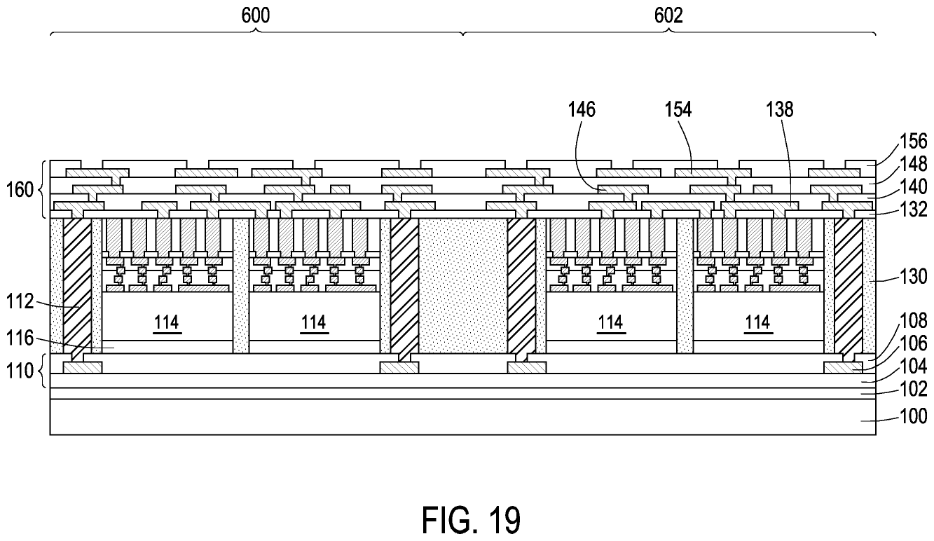

Next, as illustrated in FIGS. 7-9, 10A, 10B, 11, 12A, 12B, 13, 14A, 14B, and 15-19, a front-side redistribution structure 160 is formed. As will be illustrated in FIG. 19, the front-side redistribution structure (RDS) 160 includes dielectric layers 132, 140, 148, and 156 and metallization patterns 138, 146, and 154 (may also be referred to as redistribution layers (RDLs) 138, 146, and 154 or redistribution lines 138, 146, and 154).

In FIG. 7, the dielectric layer 132 is deposited on the encapsulant 130, through vias 112, and die connectors 126. In some embodiments, the dielectric layer 132 is formed of a polymer, which may be a photo-sensitive material such as PBO, polyimide, BCB, or the like, that may be patterned using a lithography mask. The dielectric layer 132 may be formed by spin coating, lamination, CVD, the like, or a combination thereof. In some embodiments, due to the planar upper surface of the molding material 130, the as-deposited dielectric layer 132 (e.g., a polymer layer) has a flat (e.g., level) upper surface. The dielectric layer 132 may be deposited to a thickness that is the sum of a target thickness (e.g., a thickness between about 4 μm and about 20 μm) for the dielectric layer 132 and an additional thickness, which additional thickness is between about 0.5 μm and about 3.0 μm, as an example. As discussed hereinafter, a subsequent descum process for the dielectric layer 132 will reduce the thickness of the dielectric layer 132 to its target thickness.

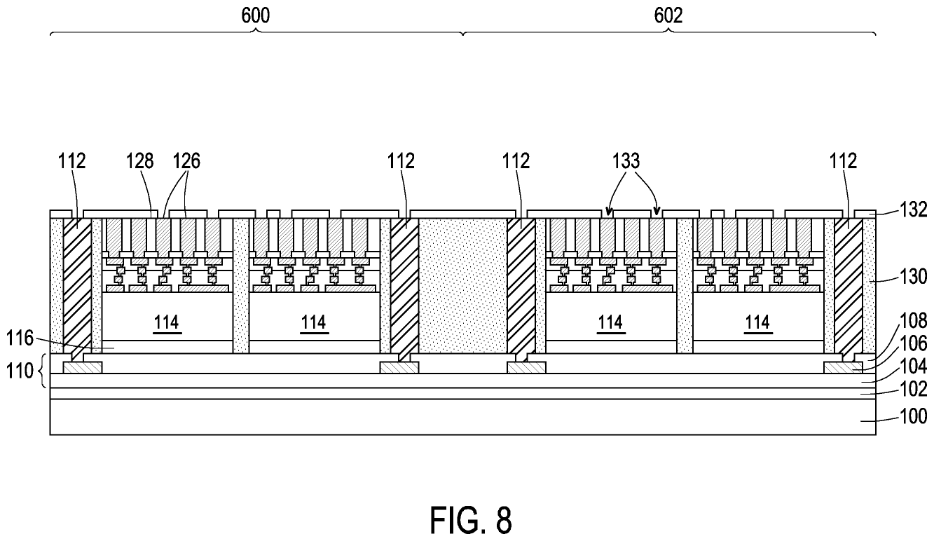

Next, in FIG. 8, the dielectric layer 132 is patterned. The patterning forms openings 133 in the dielectric layer 132 to expose portions of the through vias 112 and the die connectors 126. The patterning may be by an acceptable process, such as by exposing the dielectric layer 132 to light when the dielectric layer 132 is a photo-sensitive material or by etching using, for example, an anisotropic etch. In some embodiments where the dielectric layer 132 is a photo-sensitive material, the dielectric layer 132 is developed after the exposure, and a post-development curing process is performed next to harden the patterned dielectric layer 132.

Next, a descum process is performed to clean the openings 133, e.g., to remove, from the bottoms of the openings 133, residues that are produced by the patterning process. In some embodiments, the descum process is a plasma process performed using a gas source comprising oxygen gas or nitrogen gas. The gas source is ignited into a plasma (e.g., an oxygen plasma or a nitrogen plasma), and the plasma is used to clean the openings 133. In an example embodiment, the descum process for the dielectric layer 132 is performed at a pressure of about 70 pascals (Pa) for a duration of about 60 seconds. The process condition (e.g., pressure and process duration) for the descum process is tuned to remove residues from the bottom of the openings 133. The thickness of the dielectric layer 132 is reduced (e.g., uniformly across all locations of the dielectric layer 132) by the descum process to its target thickness, in some embodiments. The descum process roughens the upper surfaces of the dielectric layer 132. In some embodiments, after the descum process for the dielectric layer 132 is finished, a surface roughness parameter Rq of the upper surface of the dielectric layer 132 is less than about 5 nm, such as 4.5 nm. The surface roughness parameter Rq is an ISO standard parameter that indicates the root mean square (RMS) value of the surface profile height deviations from the mean line.

The process condition of the descum process performed for the dielectric layer 132 is different from that of a subsequently performed low-pressure descum process. In order to distinguish these two descum processes and for ease of discussion, the descum process (e.g., performed at about 70 pascals for about 60 seconds) performed for the dielectric layer 132 is also referred to as a point-of-reference (POR) descum process herein.

Next, a scrubber cleaning process is performed to clean the surfaces of the dielectric layer 132. Ashes or particles generated during the descum process for the dielectric layer 132 are removed by the scrubber cleaning process. In some embodiments, the scrubber cleaning process is performed using water (e.g., deionized water). A nitrogen gas (N2) may be mixed with the water to boost the pressure of the water to increase the cleaning efficiency of the scrubber cleaning process.

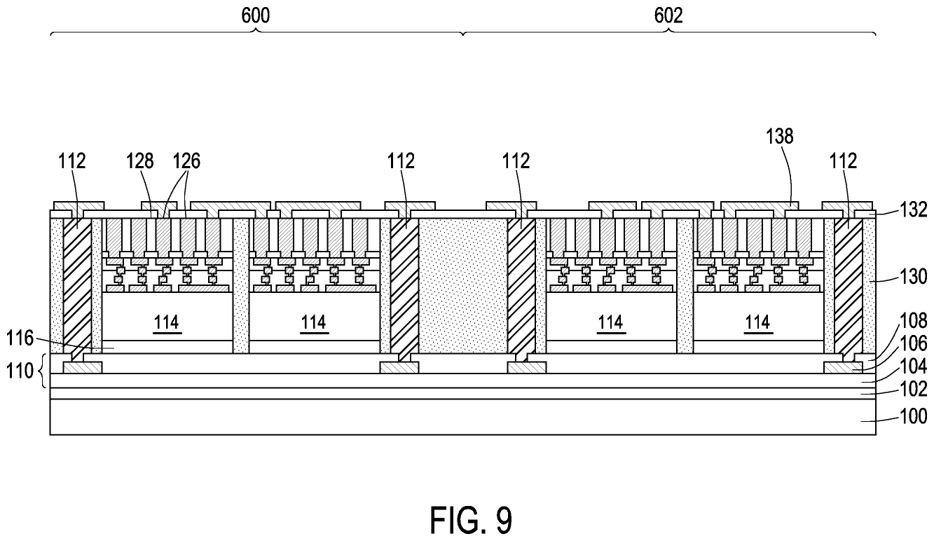

Next, in FIG. 9, metallization patterns 138 (also referred to as RDL 138) with vias are formed on the dielectric layer 132. As an example to form the metallization patterns 138, a seed layer (not shown) is formed over the dielectric layer 132 and in the openings 133 through the dielectric layer 132. In some embodiments, the seed layer is a metal layer, which may be a single layer or a composite layer comprising a plurality of sub-layers formed of different materials. In some embodiments, the seed layer comprises a titanium layer and a copper layer over the titanium layer. The seed layer may be formed using, for example, PVD or the like. A photoresist is then formed and patterned on the seed layer. The photoresist may be formed by spin coating or the like and may be exposed to light for patterning. The patterns of the photoresist correspond to the metallization patterns 138. The patterning forms openings through the photoresist to expose the seed layer. A conductive material is formed in the openings of the photoresist and on the exposed portions of the seed layer. The conductive material may be formed by plating, such as electroplating or electroless plating, or the like. The conductive material may comprise a metal, like copper, titanium, tungsten, aluminum, or the like. Then, the photoresist and portions of the seed layer on which the conductive material is not formed are removed. The photoresist may be removed by an acceptable ashing or stripping process, such as using an oxygen plasma or the like. Once the photoresist is removed, exposed portions of the seed layer are removed, such as by using an acceptable etching process, such as by wet or dry etching. The remaining portions of the seed layer and conductive material form the metallization patterns 138 and vias. The vias are formed in the openings 133 through the dielectric layer 132, and are electrically coupled to, e.g., the through vias 112 or the die connectors 126.

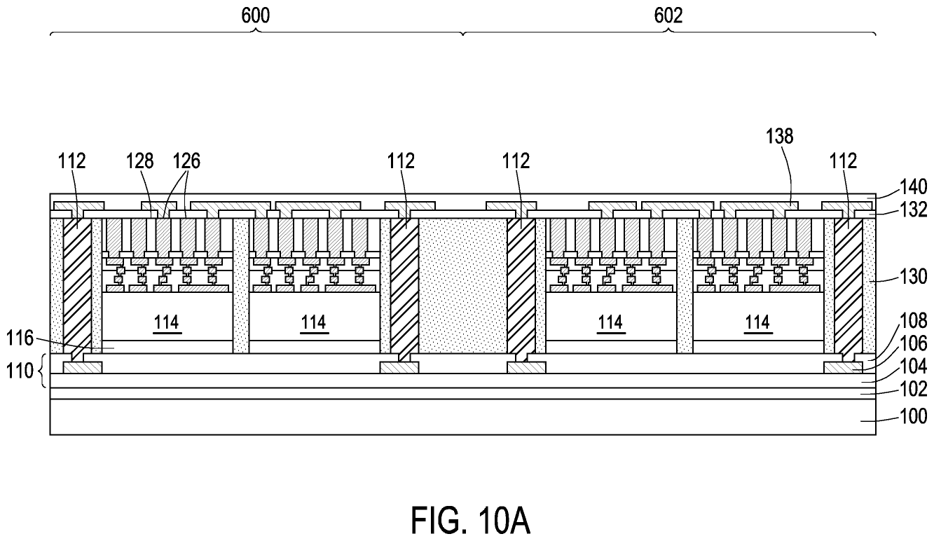

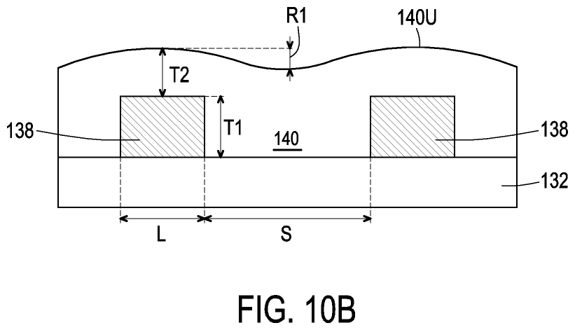

Next, in FIG. 10A, the dielectric layer 140 is deposited on the metallization patterns 138 and the dielectric layer 132. In some embodiments, the dielectric layer 140 is formed of a polymer, which may be a photo-sensitive material such as PBO, polyimide, BCB, or the like. The dielectric layer 140 may be formed by spin coating, lamination, CVD, the like, or a combination thereof. In some embodiments, all of the dielectric layers (e.g., 132, 140, 148, and 156) of the front-side RDS 160 are formed of the same material (e.g., a polymer material).

FIG. 10B illustrates a zoomed-in view of a portion of the structure of FIG. 10A. For example, FIG. 10B illustrates the dielectric layer 132, two conductive lines 138 (portions of the metallization patterns 138 disposed on the upper surface of the dielectric layer 132), and the as-deposited dielectric layer 140. In some embodiments, a thickness T1 of the conductive lines 138 is between about 2 μm and about 15 μm, a width L of the conductive line 138 is between about 1 μm and about 20 μm, a distance S between adjacent conductive lines 138 is between about 1 μm and about 100 μm, or larger, and a thickness T2 of the dielectric layer 140 over (e.g., directly over) the conductive line 138 is between about 2 μm and about 18 μm. A ratio between the distance S and the width L may be larger than one (e.g., S/L>1). A ratio between the thickness T1 and the thickness T2 may be between about 0.2 and about 5 (e.g., 0.2<T1/T2<5), such as between about 0.4 and about 1.5.

As illustrated in FIG. 10B, the thickness of the dielectric layer 140 is non-uniform, and the upper surface 140U of the dielectric layer 140 is non-flat (e.g., a wavy upper surface). The non-uniform thickness of the dielectric layer 140 may be caused by the variations in the heights and/or spacings of the underlying metallization patterns 138. The wavy upper surface of the dielectric layer 140 may cause difficulties for subsequent processing steps such as photolithography process. Therefore, it is advantageous to reduce the recess depth R1 of the dielectric layer 140, where the recess depth R1 is the vertical distance between a peak and a trough of the upper surface 140U of the dielectric layer 140.

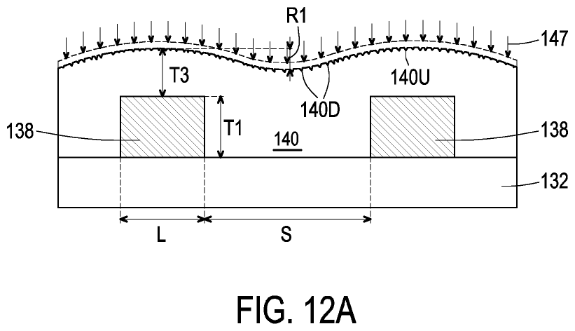

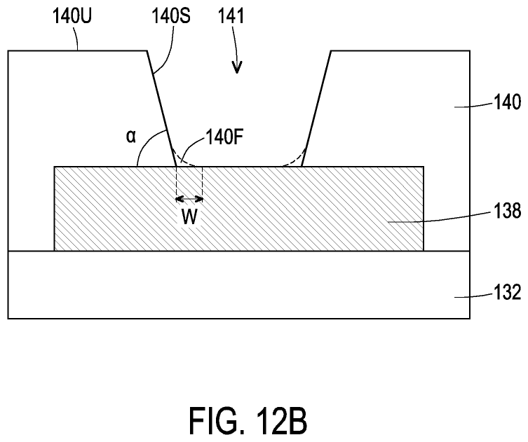

In some embodiments, in order to reduce the recess depth R1, the dielectric layer 140 is deposited to a thickness that is the sum of a target thickness (e.g., a target total thickness such as T1+T3, where T3 is shown in FIG. 12A) of the dielectric layer 140 and an additional thickness, which additional thickness is between about 0.5 μm and about 3 μm. This additional thickness increases the total thickness of the dielectric layer 140, and the planarity (e.g., flatness) of the upper surface 140U of the dielectric layer 140 with a larger thickness is less affected by the variations in the heights and/or spacings of the underlying metallization patterns 138. As a result, the recess depth R1 of the dielectric layer 140 with the additional thickness is reduced, e.g., to less than about 1.5 μm. As a comparison, if the dielectric layer 140 is formed to its target thickness without the additional thickness, the recess depth R1 of the dielectric layer 140 may be larger than about 2.3 μm.

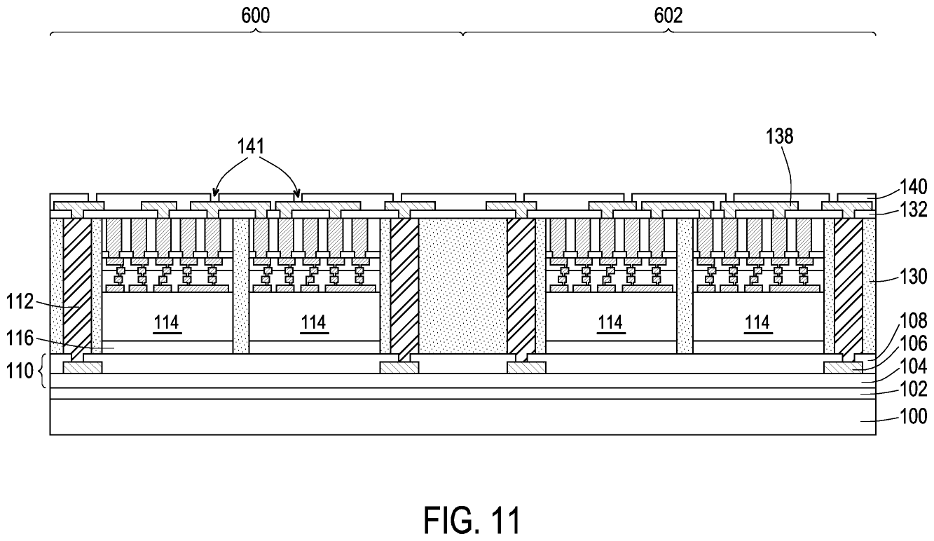

Next, in FIG. 11, the dielectric layer 140 is patterned. The patterning forms openings 141 to expose portions of the metallization pattern 138. The patterning may be by an acceptable process, such as by exposing the dielectric layer 140 to light when the dielectric layer is a photo-sensitive material or by etching using, for example, an anisotropic etch. In an embodiment where the dielectric layer 140 is a photo-sensitive material, the dielectric layer 140 is developed after the exposure, and a post-development curing process is performed next to harden the patterned dielectric layer 140.

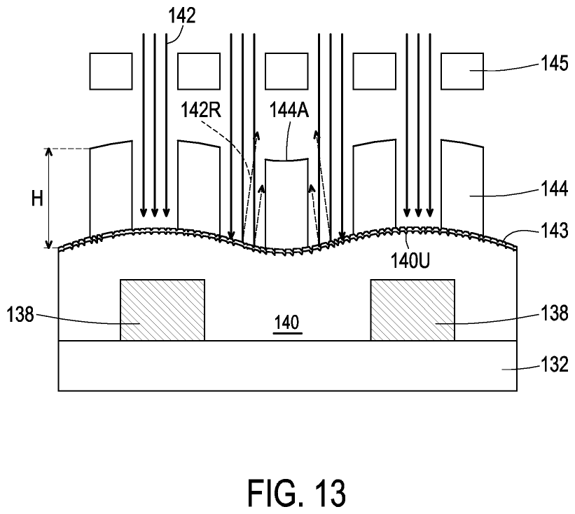

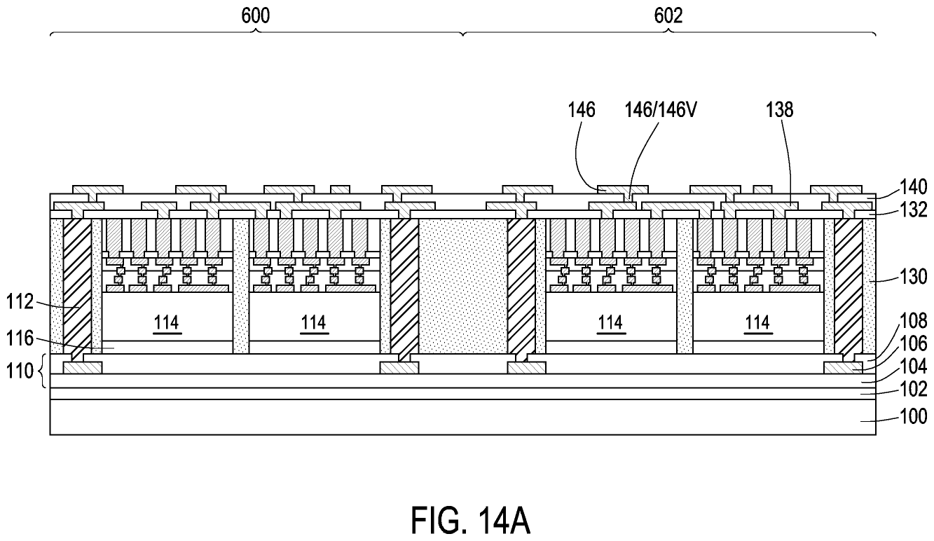

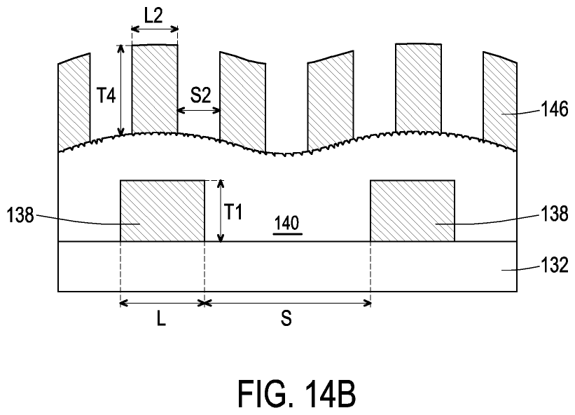

Next, in FIGS. 12A and 12B, a descum process 147 is performed to clean the openings 141 in the dielectric layer 140 (e.g., to remove residues that are produced by the patterning process). FIG. 12A (or FIG. 13 or 14B) shows a portion of the semiconductor package that corresponds to the portion shown in FIG. 10B. In some embodiments, the descum process 147 is a plasma process performed using a gas source comprising oxygen gas or nitrogen gas. The gas source is ignited into a plasma (e.g., an oxygen plasma or a nitrogen plasma), and the plasma is used to clean the openings 141. In an embodiment, the descum process 147 for the dielectric layer 140 is performed using the same gas source as the POR descum process for the dielectric layer 132, but at a lower pressure and for a longer duration of time than the POR descum process. For ease of discussion, the descum process 147 performed to treat the dielectric layer 140 is referred to as an enhanced low-pressure descum process.

In an embodiment, the enhanced low-pressure descum process 147 is performed at a pressure that is between about 30% and about 70% of the pressure of the POR descum process, and for a duration of time that is between about one time and about five times of the duration of time of the POR descum process, such as between about twice and about five times of the duration of the POR descum process. For example, while the POR descum process may be performed at a pressure of about 70 pascals and for a duration of time of about 60 seconds, the enhanced low-pressure descum process 147 may be performed at a pressure of about 35 pascals and for a duration of time between about 60 seconds and about 300 seconds.

In some embodiments, the process condition (e.g., pressure and duration) for the enhanced low-pressure descum process 147 is tuned to remove residues from the bottom of the openings 141, to reduce the thickness of the dielectric layer 140 uniformly (e.g., uniformly across all locations of the dielectric layer 140) to its target thickness, and to increase the surface roughness of the dielectric layer 140 more than the POR descum process. In some embodiments, the enhanced low-pressure descum process etches (e.g., removes) the dielectric layer 140 at a faster rate than the POR descum process, and therefore, the additional deposition thickness (e.g., the additional thickness above T1+T3) of the dielectric layer 140 may be larger than that of the dielectric layer 132, which helps to reduce the recess depth R1 of the dielectric layer 140.

As illustrated in FIG. 12A, after the enhanced low-pressure descum process 147 is finished, the upper surface 140U of the dielectric layer 140 is recessed uniformly from the location of the upper surface 140U in FIG. 10B (which is shown in dashed line in FIG. 12A). In an embodiment, a thickness T3 of the (recessed) dielectric layer 140 over (e.g., directly over) the conductive line 138 is between about 2 μm and about 15 μm. Notably, the recess depth R1 of the dielectric layer 140 in FIG. 12A is the same as the recess depth R1 of the dielectric layer 140 in FIG. 10B, which is less than about 1.5 μm. In other words, the advantage (e.g., smaller recess depth) of depositing the dielectric layer 140 to a thickness larger than its target thickness in FIG. 10B is retained by the enhanced low-pressure descum process 147. In some embodiments, a degree of planarization (DOP) of the dielectric layer 140 is calculated as DOP=(T1−R1/T1)*100%. Since the recess depth R1 of the dielectric layer 140 achieved using the larger deposition thickness (e.g., target thickness with an addition thickness of 0.5 μm to 3 μm) and the enhanced lower-pressure descum process 147 is smaller than that achieved using a smaller deposition thickness and the POR descum process, the DOP of the dielectric layer 140 is higher than that if a smaller deposition thickness and the POR descum process is used. For example, the DOP achieved by using the larger deposition thickness and the enhanced low-pressure descum process 147 may be larger than about 79%, and the DOP achieved using the smaller deposition thickness and the POR descum process may be smaller than about 70%.

In addition, the enhanced low-pressure descum process 147 roughens the upper surfaces of the dielectric layer 140 significantly. FIG. 12A illustrates a plurality of divots 140D at the upper surface 140U of the dielectric layer 140. The magnitudes of the divots 140D may be exaggerated to show the significantly increased surface roughness of the dielectric layer 140. In some embodiments, after the enhanced low-pressure descum process 147 is finished, a surface roughness parameter Rq of the upper surface of the dielectric layer 140 is between about 1.5 times and about 10 times, such as between twice and about ten times, of the surface roughness parameter Rq of the dielectric layer 132 after the POR descum process. For example, the POR descum process may result in a surface roughness parameter Rq of less than about 5 nm, such as 4.5 nm, for the dielectric layer 132. In contrast, the enhanced low-pressure descum process 147 may result in a surface roughness parameter Rq of between about 7 nm and about 40 nm for the dielectric layer 140. As will be discussed hereinafter, the higher surface roughness caused by the enhanced low-pressure descum process 147 results in a significantly reduced reflectivity of a subsequently formed seed layer 143 (see FIG. 13), which achieves further advantage as discussed hereinafter.

Note that FIG. 12A shows a portion of the semiconductor package that does not have an opening 141 in the dielectric layer 140. FIG. 12B shows another portion of the semiconductor package that has an opening 141 in the dielectric layer 140. For simplicity, the upper surface 140U of the dielectric layer 140 in FIG. 12B is shown as flat in FIG. 12B, with the understanding the upper surface 140U may not be flat and may have divots due to the increased surface roughness.

As illustrated in FIG. 12B, the opening 141 exposes sidewalls 140S of the dielectric layer 140 and an underlying conductive line 138. The sidewalls 140S are slanted with respect to the horizontal direction of FIG. 12B, and forms an angle α with the upper surface of the conductive line 138. The opening 141 in FIG. 12B has a trapezoidal cross-section. In other words, the distance between opposing sidewalls 140S exposed by the opening 141 decreases as the opening 141 extends toward the conductive line 138. In some embodiments, the enhanced low-pressure descum process 147 is able to better remove residues from the opening 141 than the POR descum process, thereby creating a better sidewall profile, with the sidewalls 140S being closer to be perpendicular to the horizontal direction of FIG. 12B. In other words, if the POR descum process is performed to clean the opening 141, the angle α created by the POR descum process would be smaller than that created by the enhance low-pressure descum process 147. The better sidewall profile allows for better overlay control in photolithography.

FIG. 12B further illustrates, in dashed line, a footing 140F at the bottom of each sidewall 140S of the dielectric layer 140. The footing 140F represents a protrusion portion of the dielectric layer 140 that protrudes into the opening 141. In subsequent process, the opening 141 is filled with a conductive material to form a via. The footing 140F reduces the contact area between the via and the conductive line 138, thus increasing the contact resistance. In addition, after the opening 141 is filled with the conductive material to form a via, the area around the footing 140F experiences higher stress and is at higher risk for failure such as delamination or cracking. In some embodiments, the width W of the footing 140F after the enhanced low-pressure descum process 147 is smaller than that after the POR descum process. This illustrates another advantage (e.g., lower contact resistance, less stress) of the enhanced low-pressure descum process 147. For example, if the POR descum process is performed to clean the opening 141, the width W of the footing 140F may be larger than about 0.6 μm. In contrast, if the enhanced low-pressure descum process 147 is performed to clean the opening 141, the width W of the footing 140F may be smaller than about 0.6 μm. Note that since the opening 141 is filled subsequently to form a via (see, e.g., the via 146V in FIG. 14A), the shape and dimension of the opening 141 correspond to those of the subsequently formed via.

Next, after the enhanced low-pressure descum process 147, a scrubber cleaning process is performed to clean the surfaces of the dielectric layer 140. Ashes or particles generated during the descum process for the dielectric layer 140 are removed by the scrubber cleaning process. The scrubber cleaning process may be the same as or similar to the scrubber cleaning process discussed above, thus details are not repeated.

Next, in FIG. 13, a seed layer 143 is formed (e.g., conformally) on the upper surface 140U of the dielectric layer 140 and in the openings 141 through the dielectric layer 140. In some embodiments, the seed layer 143 is a metal layer, which may be a single layer or a composite layer comprising a plurality of sub-layers formed of different materials. In some embodiments, the seed layer 143 comprises a titanium layer and a copper layer over the titanium layer. The seed layer 143 may be formed using, for example, PVD or the like.

Due to the upper surface 140U having a high surface roughness parameter Rq, the seed layer 143 also has a high surface roughness parameter Rq same as or similar to that of the dielectric layer 140. The high surface roughness of the seed layer 143 results in a low reflectivity of the seed layer 143, where reflectivity may be calculated as the percentage of an incident light energy reflected by the seed layer 143. In an embodiment, the reflectivity of the seed layer (e.g., 143) formed over a surface (e.g., 140U) of the dielectric layer (e.g., 140) treated by the enhanced low-pressure descum process is lower than (e.g., is about one third or less) that of the seed layer formed over the surface if the surface is treated by the POR descum process. For example, the reflectivity of the seed layer formed over the dielectric layer 132 is about 45%, and the reflectivity of the seed layer 143 formed over the dielectric layer 140 is about 15% or less.

Next, a photoresist 144 is formed and patterned on the seed layer 143. The photoresist 144 may be formed by spin coating or the like and may be exposed to light for patterning. In the example of FIG. 13, a light source 142 is projected through a photo mask 145 to expose the photoresist 144. After exposure, the photoresist 144 is developed, and a post-development curing process is performed next to harden the patterned photoresist 144, in some embodiments. The patterns of the photoresist 144 correspond to the metallization patterns 146 (see FIG. 14A) formed subsequently. The patterning of the photoresist 144 forms openings through the photoresist 144 to expose the seed layer 143.

As illustrated in FIG. 13, a portion of the light source 142, referred to as reflected light source 142R, is reflected by the seed layer 143. The reflected light source 142R may expose the photoresist 144, and therefore, distort the patterns of the patterned photoresist 144. In the example of FIG. 13, if the reflected light source 142R (shown in dashed arrow lines) is strong enough, the reflected light source 142R may expose a top layer of a portion 144A of the photoresist 144, and therefore, reduce the height of the portion 144A (e.g., after development). In subsequent processing, when an electrically conductive material is formed to fill the openings in the photoresist 144, the electrically conductive material may flow over the top surface of the portion 144A (which has a reduced height relative to other portions of the photoresist 144) and causing a bridging issue (e.g., electrical short) between metallization patterns formed on opposing sides of the portion 144A of the photo resist 144, thereby resulting in device failure and yield loss.

Recall that the enhanced low-pressure descum process 147 causes increased surface roughness and lower reflectivity for the seed layer 143. Due to the low reflectivity, only a small portion (e.g., 15% or less) of the incident light energy is reflected, which prevents or alleviates the effect of the reflected light source 142R exposing the photoresist 144. The increase surface roughness also causes the reflected light source 142R to travel in random directions, thus diffusing the reflected light energy and preventing the reflected light energy from being focused at a certain area, further reducing the likelihood of the bridging issue. Therefore, the seed layer 143, with its low reflectivity and high surface roughness, functions as a bottom anti-reflective coating (BARC) for the photoresist 144.

Next, in FIG. 14A, a conductive material is formed in the openings of the photoresist 144 and on the exposed portions of the seed layer 143. The conductive material may be formed by plating, such as electroplating or electroless plating, or the like. The conductive material may comprise a metal, like copper, titanium, tungsten, aluminum, or the like. Then, the photoresist 144 and portions of the seed layer 143 on which the conductive material is not formed are removed. The photoresist 144 may be removed by an acceptable ashing or stripping process, such as using an oxygen plasma or the like. Once the photoresist 144 is removed, exposed portions of the seed layer 143 are removed, such as by using an acceptable etching process, such as by wet or dry etching. The remaining portions of the seed layer 143 and conductive material form the metallization pattern 146, which includes conductive lines over the upper surface of the dielectric layer 140 and vias 146V. The vias 146V are formed in openings through the dielectric layer 140 and are electrically coupled to, e.g., portions of the metallization patterns 138.

FIG. 14B shows a portion of the semiconductor package in FIG. 14A. In the example of FIG. 14B, a plurality of conductive lines 146 (e.g., portions of the metallization patterns 146 disposed over the upper surface of the dielectric layer 140) are illustrated on the dielectric layer 140. FIG. 14B further illustrates conductive lines 138 embedded in the dielectric layer 140 and on the dielectric layer 132. Note that the portion of semiconductor package shown in FIG. 14B does not contain the via 146V (see FIG. 14A), which extends through the dielectric layer 140.

In some embodiments, due to use of the enhanced low-pressure descum process 147 reducing or avoiding the bridging issue, the thickness T4 of the conductive line 146 can be formed to be larger than the thickness achievable when the POR descum process is used. As a result of the larger thickness T4, the width L2 of the conductive line 146 can be formed to be smaller while still maintaining the same electrical resistance (e.g., due to the cross-section area of the conductive line 146 being unchanged). In addition, the disclosed method also allows the pitch S2 between adjacent conductive lines 146 to be reduced compared with the pitch achievable when the POR descum process is used. The smaller width L2 and smaller pitch S2 of the conductive line 146 allow for a higher level of routing density without loss of electrical performance, or alternatively, a higher level of electrical performance (e.g., lower electrical resistance) at the same level of routing density. In the example of FIG. 14B, the width L2, the thickness T4, and the pitch S2 of the conductive line 146 are smaller than the width L, the thickness T1, and the pitch S of the conductive line 138, respectively. In some embodiments, the width L, the thickness T1, and the pitch S of the conductive line 138 shown in FIG. 14B are representative of (e.g., the same as or similar to) the width, the thickness, and the pitch, respectively, of conductive lines in a redistribution layer of the front-side redistribution structure 160, if the POR descum process is used to treat the dielectric layer on which that redistribution layer is formed.

Next, the same processing steps for forming the dielectric layer 140 and the metallization patterns 146, as illustrated in FIGS. 10A, 10B, 11, 12A, 12B, 13, 14A, and 14B, are repeated to form additional layers of dielectric layers and additional layers of metallization patterns for the front-side redistribution structure 160.

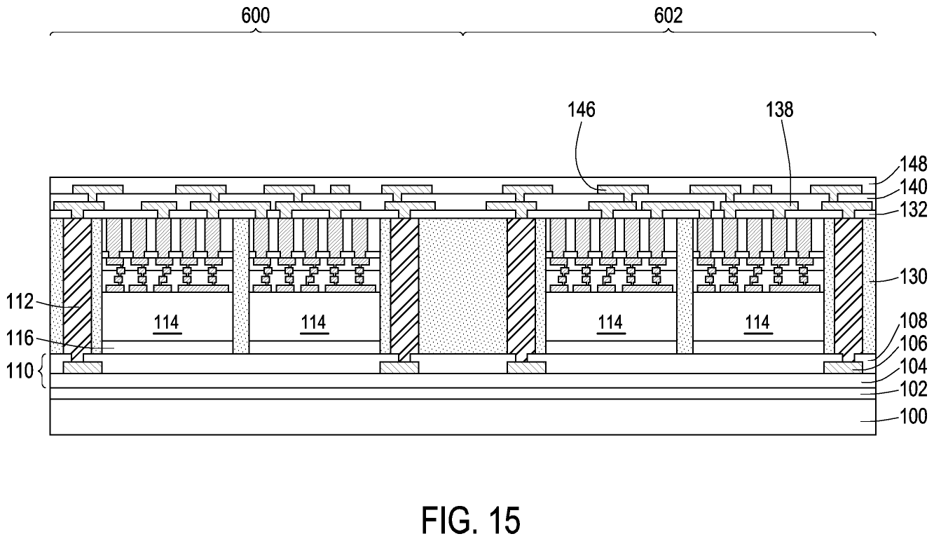

In FIG. 15, a dielectric layer 148 is deposited on the metallization pattern 146 and the dielectric layer 140. The dielectric layer 148 may be formed of a same material as the dielectric layer 140 using the same formation method, thus details may not be repeated. The dielectric layer 148 may be formed to have a thickness that is equal to the sum of the target thickness of the dielectric layer 148 and an additional thickness (e.g., a thickness between about 0.5 μm and about 3 μm).

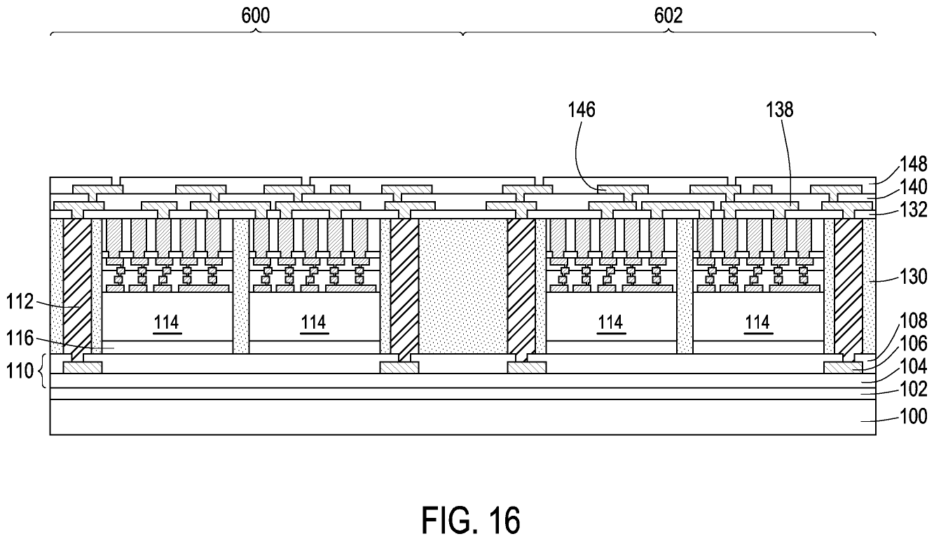

Next, in FIG. 16, the dielectric layer 148 is patterned, using the same or similar patterning process as discussed above for the dielectric layer 140, thus details are not repeated. The patterning forms openings in the dielectric layer 148 to expose portions of the metallization pattern 146.

Next, the enhanced low-pressure descum process, which is discussed above, is performed to treat the dielectric layer 148. The enhanced low-pressure descum process reduces the thickness of the dielectric layer 148 to its target thickness, and results in a high surface roughness parameter Rq between, e.g., about 7 nm and about 40 nm for the dielectric layer 148. Next, the scrubber cleaning process, which is discussed above, is performed to remove particles generated by the enhanced low-pressure descum process.

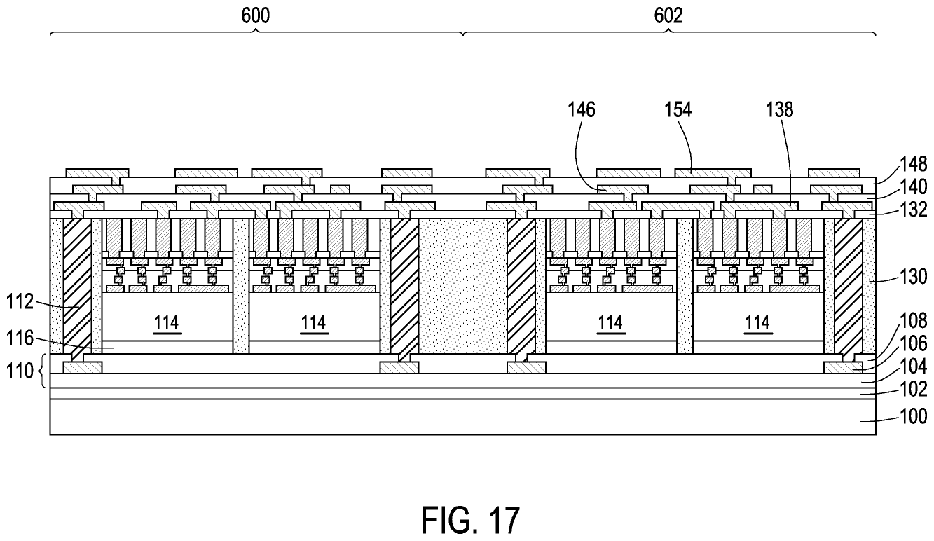

Next, in FIG. 17, metallization patterns 154 with vias are formed on the dielectric layer 148. For example, a seed layer (not shown) is formed over the dielectric layer 148 and in openings through the dielectric layer 148. The seed layer has a low reflectivity (e.g., 15% or lower). A photoresist is then formed and patterned on the seed layer. The patterns of the photoresist correspond to the metallization patterns 154. The patterning forms openings through the photoresist to expose the seed layer. A conductive material is formed in the openings of the photoresist and on the exposed portions of the seed layer. Then, the photoresist and portions of the seed layer on which the conductive material is not formed are removed. The remaining portions of the seed layer and conductive material form the metallization pattern 154 and vias. The vias are formed in openings through the dielectric layer 148 to, e.g., portions of the metallization pattern 146. Details are the same as or similar to those discussed above for the metallization patterns 146, thus are not repeated.

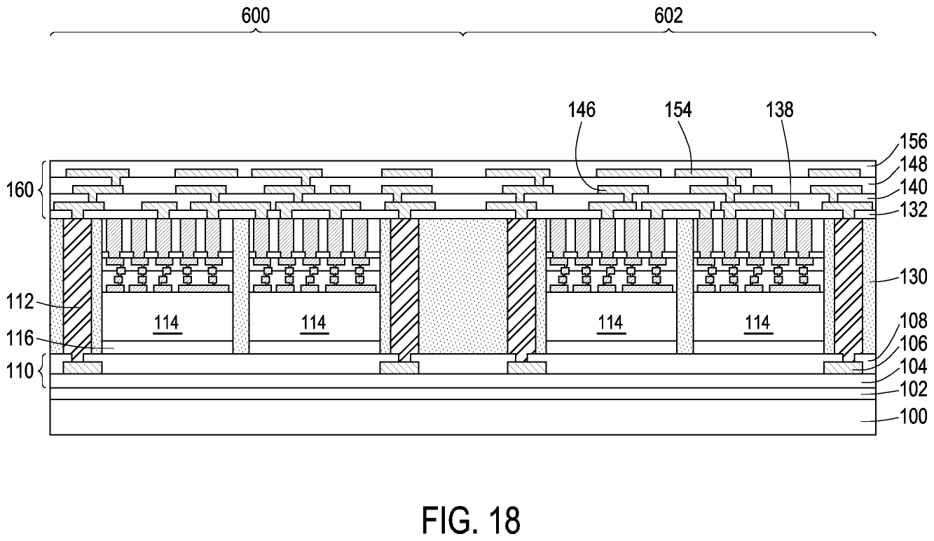

Next, in FIG. 18, the dielectric layer 156 is deposited on the metallization pattern 154 and the dielectric layer 148. In some embodiments, the dielectric layer 156 is formed of a same material (e.g., a polymer material) as the dielectric layer 140 using the same formation method, thus details are not repeated.

Next, in FIG. 19, the dielectric layer 156 is patterned. The patterning forms openings to expose portions of the metallization pattern 154. The enhanced low-pressure descum process is performed to clean the openings, to reduce the thickness of the dielectric layer 156 to its target thickness, and to increase its surface roughness parameter Rq to a range of, e.g., between about 7 nm and about 40 nm for the dielectric layer 156. Next, the scrubber cleaning process is performed to remove particles generated by the enhanced low-pressure descum process. Details are similar to those discussed above, thus not repeated.

The front-side redistribution structure 160 shown in FIG. 19 is a non-limiting example. More or fewer dielectric layers and metallization patterns may be formed in the front-side redistribution structure 160. If fewer dielectric layers and metallization patterns are to be formed, steps and process discussed above may be omitted. If more dielectric layers and metallization patterns are to be formed, steps and processes discussed above may be repeated. One having ordinary skill in the art will readily understand which steps and processes would be omitted or repeated.

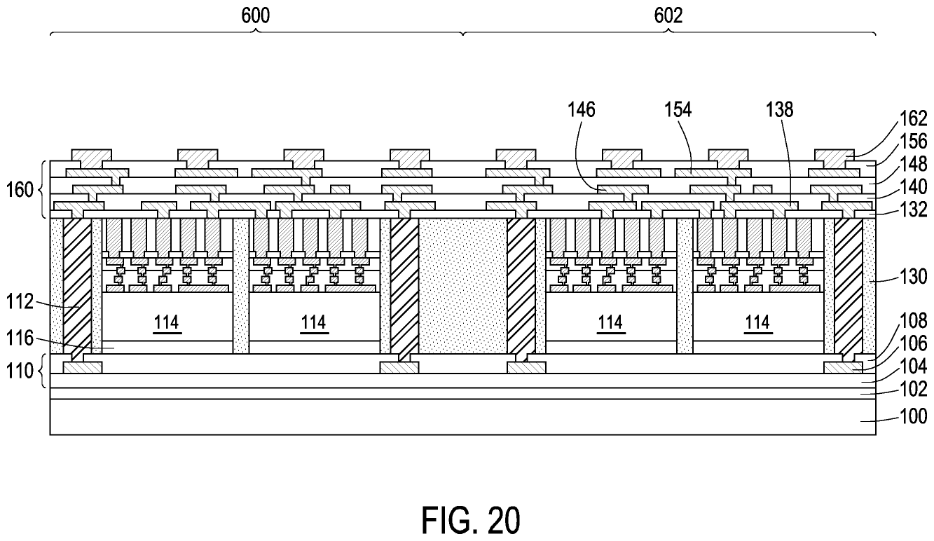

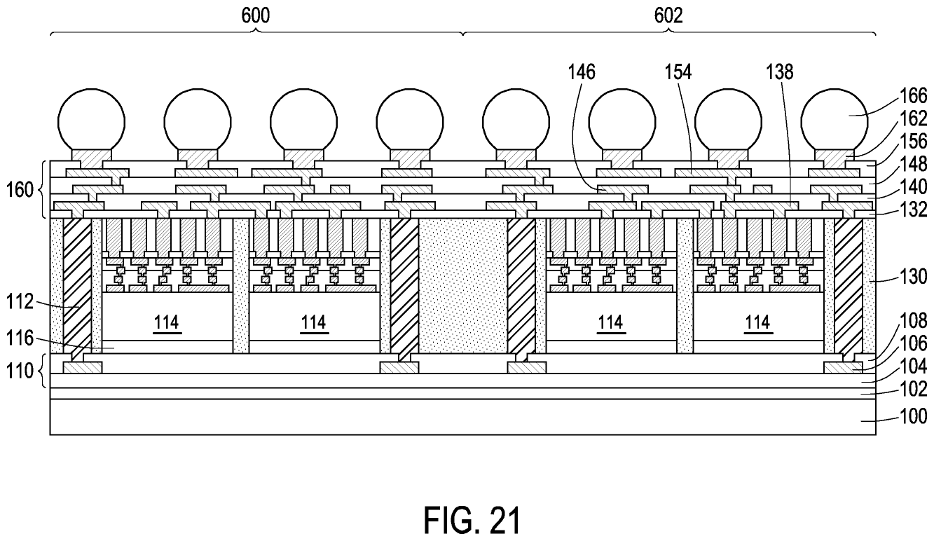

Next, in FIG. 20, pads 162 are formed on an exterior side of the front-side redistribution structure 160. The pads 162 are used to couple to conductive connectors 166 (see FIG. 21) and may be referred to as under bump metallurgies (UBMs) 162. In the illustrated embodiment, the pads 162 are formed to extend through openings in the dielectric layer 156 to the metallization pattern 154. As an example to form the pads 162, a seed layer (not shown) is formed over the dielectric layer 156 and in the opening in the dielectric layer 156. In some embodiments, the seed layer is a metal layer, which may be a single layer or a composite layer comprising a plurality of sub-layers formed of different materials. In some embodiments, the seed layer comprises a titanium layer and a copper layer over the titanium layer. The seed layer may be formed using, for example, PVD or the like. A photoresist is then formed and patterned on the seed layer. The photoresist may be formed by spin coating or the like and may be exposed to light for patterning. The patterns of the photoresist correspond to the pads 162. The patterning forms openings through the photoresist to expose the seed layer. A conductive material is formed in the openings of the photoresist and on the exposed portions of the seed layer. The conductive material may be formed by plating, such as electroplating or electroless plating, or the like. The conductive material may comprise a metal, like copper, titanium, tungsten, aluminum, or the like. Then, the photoresist and portions of the seed layer on which the conductive material is not formed are removed. The photoresist may be removed by an acceptable ashing or stripping process, such as using an oxygen plasma or the like. Once the photoresist is removed, exposed portions of the seed layer are removed, such as by using an acceptable etching process, such as by wet or dry etching. The remaining portions of the seed layer and conductive material form the pads 162.

Next, in FIG. 21, conductive connectors 166 are formed on the UBMs 162. The conductive connectors 166 may be BGA connectors, solder balls, metal pillars, controlled collapse chip connection (C4) bumps, micro bumps, electroless nickel-electroless palladium-immersion gold technique (ENEPIG) formed bumps, or the like. The conductive connectors 166 may include a conductive material such as solder, copper, aluminum, gold, nickel, silver, palladium, tin, the like, or a combination thereof. In some embodiments, the conductive connectors 166 are formed by initially forming a layer of solder through such commonly used methods such as evaporation, electroplating, printing, solder transfer, ball placement, or the like. Once a layer of solder has been formed on the structure, a reflow may be performed in order to shape the material into the desired bump shapes. In another embodiment, the conductive connectors 166 are metal pillars (such as a copper pillar) formed by a sputtering, printing, electro plating, electroless plating, CVD, or the like. The metal pillars may be solder free and have substantially vertical sidewalls. In some embodiments, a metal cap layer (not shown) is formed on the top of the metal pillar connectors 166. The metal cap layer may include nickel, tin, tin-lead, gold, silver, palladium, indium, nickel-palladium-gold, nickel-gold, the like, or a combination thereof and may be formed by a plating process.

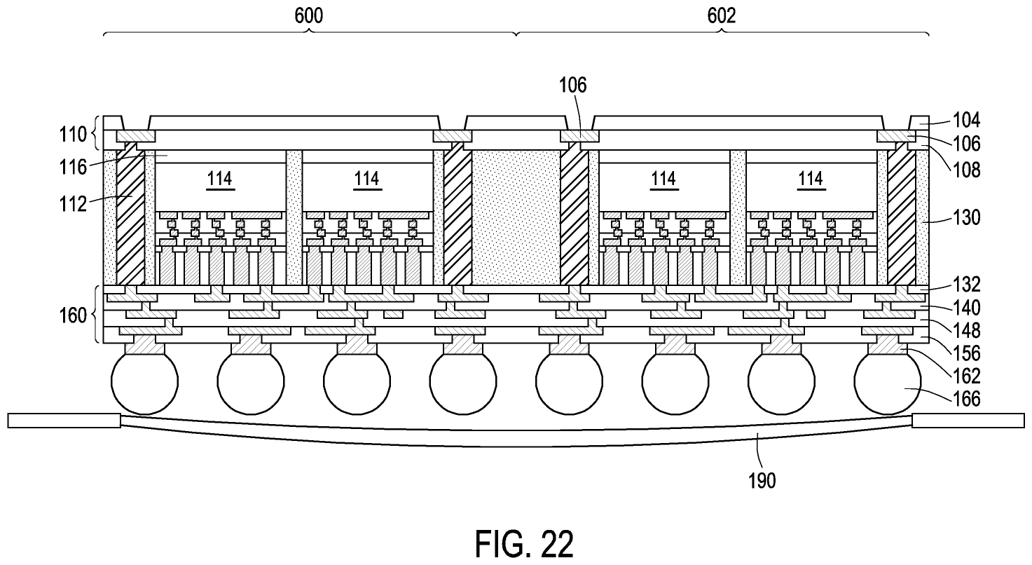

Next, in FIG. 22, a carrier substrate de-bonding process is performed to detach (de-bond) the carrier substrate 100 from the back-side redistribution structure, e.g., dielectric layer 104. In accordance with some embodiments, the de-bonding includes projecting a light such as a laser light or an UV light on the release layer 102 so that the release layer 102 decomposes under the heat of the light and the carrier substrate 100 can be removed. The structure is then flipped over and placed on a tape 190.

As further illustrated in FIG. 22, openings are formed through the dielectric layer 104 to expose portions of the metallization pattern 106. The openings may be formed, for example, using laser drilling, etching, or the like.

Next, a singulation process is performed by sawing along scribe line regions (e.g., between adjacent regions 600 and 602). The sawing singulates the first package region 600 from the second package region 602.

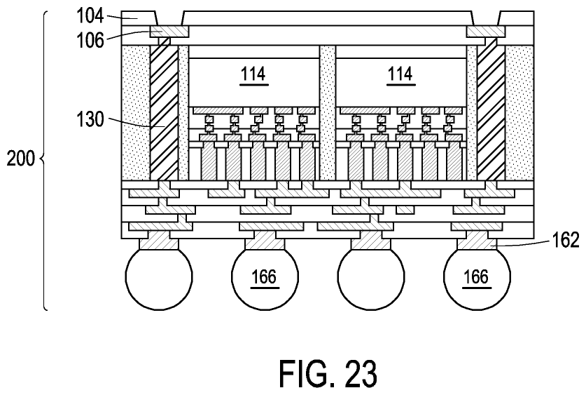

FIG. 23 illustrates a resulting, singulated package 200, which may be from one of the first package region 600 or the second package region 602. The package 200 may also be referred to as an integrated fan-out (InFO) package 200.

FIG. 24 illustrates a package structure 500 including the package 200 (may also be referred to as a first package 200, or a bottom package 200) and a second package 300 (may also be referred to as a top package 300). The second package 300 includes a substrate 302 and one or more stacked dies 308 (e.g., 308A and 308B) coupled to the substrate 302. Although a singular stack of dies 308 (e.g., 308A and 308B) is illustrated, in other embodiments, a plurality of stacked dies 308 (each having one or more stacked dies) may be disposed side by side coupled to a same surface of the substrate 302.

In FIG. 24, the substrate 302 may be made of a semiconductor material such as silicon, germanium, diamond, or the like. In some embodiments, compound materials such as silicon germanium, silicon carbide, gallium arsenic, indium arsenide, indium phosphide, silicon germanium carbide, gallium arsenic phosphide, gallium indium phosphide, combinations of these, and the like, may also be used. Additionally, the substrate 302 may be a silicon-on-insulator (SOI) substrate. Generally, an SOI substrate includes a layer of a semiconductor material such as epitaxial silicon, germanium, silicon germanium, SOI, silicon germanium on insulator (SGOI), or combinations thereof. The substrate 302 is, in one alternative embodiment, based on an insulating core such as a fiberglass reinforced resin core. One example core material is fiberglass resin such as FR4. Alternatives for the core material include bismaleimide-triazine (BT) resin, or alternatively, other printed circuit board (PCB) materials or films. Build up films such as Ajinomoto build-up film (ABF) or other laminates may be used for substrate 302.

The substrate 302 may include active and passive devices (not shown in FIG. 24). As one of ordinary skill in the art will recognize, a wide variety of devices such as transistors, capacitors, resistors, combinations of these, and the like may be used to meet the structural and functional requirements of the design for the second package 300. The devices may be formed using any suitable methods.

The substrate 302 may also include metallization layers (not shown) and through vias 306. The metallization layers may be formed over the active and passive devices and are designed to connect the various devices to form functional circuitry. The metallization layers may be formed of alternating layers of dielectric (e.g., low-k dielectric material) and conductive material (e.g., copper) with vias interconnecting the layers of conductive material and may be formed through any suitable process (such as deposition, damascene, dual damascene, or the like). In some embodiments, the substrate 302 is substantially free of active and passive devices.

The substrate 302 may have bond pads 303 on a first side the substrate 302 to couple to the stacked dies 308, and bond pads 304 on a second side of the substrate 302, the second side being opposite the first side of the substrate 302, to couple to the functional connectors 314.

In the illustrated embodiment, the stacked dies 308 are coupled to the substrate 302 by wire bonds 310, although other connections may be used, such as conductive bumps. In an embodiment, the stacked dies 308 are stacked memory dies. For example, the stacked memory dies 308 may include low-power (LP) double data rate (DDR) memory modules, such as LPDDR1, LPDDR2, LPDDR3, LPDDR4, or the like memory modules.

In some embodiments, the stacked dies 308 and the wire bonds 310 may be encapsulated by a molding material 312. The molding material 312 may be molded on the stacked dies 308 and the wire bonds 310, for example, using compression molding. In some embodiments, the molding material 312 is a molding compound, a polymer, an epoxy, silicon oxide filler material, the like, or a combination thereof. A curing step may be performed to cure the molding material 312, wherein the curing may be a thermal curing, a UV curing, the like, or a combination thereof.

After the second package 300 is formed, the second package 300 is mechanically and electrically bonded to the first package 200 by way of functional connectors 314, the bond pads 304, and the metallization pattern 106. The functional connectors 314 may be similar to the conductive connectors 166 described above and the description is not repeated here, although the functional connectors 314 and the conductive connectors 166 need not be the same.

The bonding between the second package 300 and the first package 200 may be a solder bonding. In an embodiment, the second package 300 is bonded to the first package 200 by a reflow process. During this reflow process, the functional connectors 314 are in contact with the bond pads 304 and the metallization patterns 106 to physically and electrically couple the second package 300 to the first package 200. After the bonding process, an intermetallic compound (IMC, not shown) may form at the interface of the metallization patterns 106 and the functional connectors 314 and also at the interface between the functional connectors 314 and the bond pads 304 (not shown).

Variations to the disclosed embodiment are possible, and are fully intended to be included within the scope of the disclosure. For example, in the illustrated embodiment discussed above for forming the front-side redistribution structure 160, the dielectric layer 132 of the front-side redistribution structure 160 is treated by the POR descum process, while the other dielectric layers (e.g., 140, 148, 156) of the front-side redistribution structure 160 are treated by the enhanced low-pressure descum process. This embodiment is suitable when the surface of the molding material 130 facing the front-side redistribution structure 160 is a planar surface, in which case the recess depth R1 of the as-deposited dielectric layer 132 is very small, and the flat surface of the molding material 130 does not cause bridging issue (e.g., because the reflected light source is reflected straight upwards).

As another embodiment, if, however, the surface of the molding material 130 facing the front-side redistribution structure 160 has molding pits (e.g., tiny cavities), then the dielectric layer 132 and the metallization patterns 138 may be formed using the same processing steps for the dielectric layer 140 and the metallization patterns 146. For example, the enhanced low-pressure descum process may be used to treat the dielectric layer 132 after openings are formed in the dielectric layer 132. In other words, both the dielectric layers 132 and 140 are deposited to a larger thickness (e.g., the target thickness plus an additional thickness), and both are treated using the enhanced low-pressure descum process. For the remaining dielectric layers 148 and 156 in the front-side redistribution structure 160, a criteria is used to determine whether the POR descum process or the enhanced low-pressure descum process should be used to treat each of the dielectric layers 148 and 156. An example of such a criteria is based on the topology of the underlying metallization patterns on which the dielectric layer 148 (or 156) is formed and the target thickness of the dielectric layer 148 (or 156). For ease of discussion, refer to FIG. 10B and pretend that the conductive line 138 is the “underlying metallization patterns” for the dielectric layer 148 (or 156), and that the dielectric layer 140 is the dielectric layer 148 (or 156). Using the notation in FIG. 10B, if the ratio between the pitch S and the width L of the underlying conductive line is larger than 1 (e.g., S/L>1), and if the thickness T1 of the underlying conductive line is larger than or equal to the target thickness T2 of the portion of the dielectric layer 148 (or 156) directly over the underlying conductive line (e.g., T1>T2), then the enhanced low-pressure descum process is used for the dielectric layer 148 (or 156); otherwise, the POR descum process is used.

Those skilled in the art will readily appreciate other variations to the disclosed embodiments. For example, depending on the planarity (e.g., whether the exterior surface of the molding material 132 has molding pits) of the exterior surface of the molding material 130, the POR descum process or the enhanced low-pressure descum process is used to treat the dielectric layer 132. For each of the other dielectric layers (e.g., 140, 148, and 156), the criteria discussed above (e.g., S/L>1 and T1≥T2) is used to determine whether the POR descum process or the enhanced low-pressure descum process is used to treat the dielectric layer. Note that when the POR descum process is used to treat a dielectric layer (e.g., 132, 140, 148, or 156), the size, shape, and physical properties (e.g., surface roughness, reflectivity, sidewall profile, footing size, conductive line thickness, and pitch between conductive lines) of components resulting from, or affected by, the POR descum process have the same or similar values/properties as discussed above in the context of comparison between the POR descum process and the enhanced low-pressure descum process.

Embodiments of the device and methods in the current disclosure have many advantages. The enhanced low-pressure descum process not only cleans the openings in the dielectric layer, but also increases the surface roughness of the dielectric layer. As a result of the increased surface roughness, the seed layer formed subsequently has a lower reflectivity, which reduces or alleviates the bridging issue. As a result, device failure rate is reduced, and production yield is improved. The enhanced low-pressure descum process also provides better sidewall profile for the openings in the dielectric layer, and reduces the width of the footing. The better sidewall profile allows for better overlay control, and the smaller footing results in less stress related issues (e.g., delamination, cracking). The disclosed criteria may be used to determine whether the POR descum process (e.g., having a shorter process duration) or the enhanced low-pressure descum process (e.g., having a longer process duration) is used for each dielectric layer of the redistribution structure. This ensures that the enhanced low-pressure descum process is used for some dielectric layers only when needed, thus reducing production time and cost, since the POR descum process can be used for other dielectric layers to shorten production time.

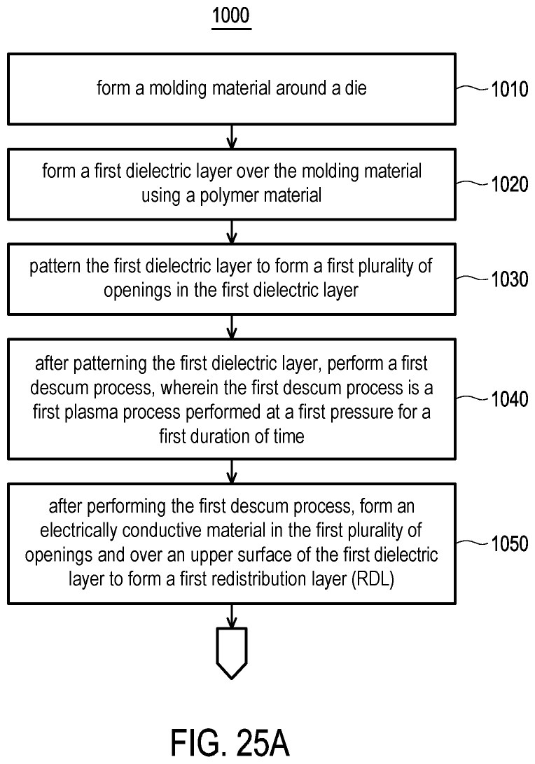

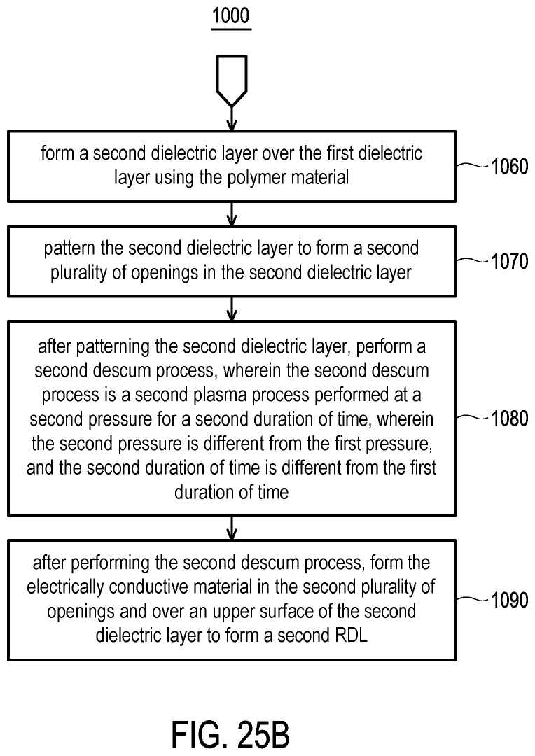

FIGS. 25A and 25B together illustrate a flow chart of a method 1000 of forming a semiconductor package, in an embodiment. It should be understood that the embodiment method shown in FIGS. 25A and 25B is merely an example of many possible embodiment methods. One of ordinary skill in the art would recognize many variations, alternatives, and modifications. For example, various steps as illustrated in FIGS. 25A and 25B may be added, removed, replaced, rearranged, or repeated.

Referring to FIGS. 25A and 25B, at block 1010, a molding material is formed around a die. At block 1020, a first dielectric layer is formed over the molding material using a polymer material. At block 1030, the first dielectric layer is patterned to form a first plurality of openings in the first dielectric layer. At block 1040, after patterning the first dielectric layer, a first descum process is performed, wherein the first descum process is a first plasma process performed at a first pressure for a first duration of time. At block 1050, after performing the first descum process, an electrically conductive material is formed in the first plurality of openings and over an upper surface of the first dielectric layer to form a first redistribution layer (RDL). At block 1060, a second dielectric layer is formed over the first dielectric layer using the polymer material. At block 1070, the second dielectric layer is patterned to form a second plurality of openings in the second dielectric layer. At block 1080, after patterning the second dielectric layer, a second descum process is performed, wherein the second descum process is a second plasma process performed at a second pressure for a second duration of time, wherein the second pressure is different from the first pressure, and the second duration of time is different from the first duration of time. At block 1090, after performing the second descum process, the electrically conductive material is formed in the second plurality of openings and over an upper surface of the second dielectric layer to form a second RDL.

In accordance with an embodiment, a method of forming a semiconductor package includes: surrounding a die with a molding material; and forming a redistribution structure (RDS) over the molding material and electrically coupled to the die, which comprises: depositing a first dielectric layer over the molding material; patterning the first dielectric layer to form a first plurality of openings in the first dielectric layer; performing a first descum process to clean the first plurality of openings; after performing the first descum process, forming a first redistribution layer (RDL) on the first dielectric layer; depositing a second dielectric layer over the molding material; patterning the second dielectric layer to form a second plurality of openings in the second dielectric layer; performing a second descum process to clean the second plurality of openings, wherein the first descum process and the second descum process are performed under different process conditions; and after performing the second descum process, forming a second RDL on the second dielectric layer. In an embodiment, the first descum process is performed under a first process condition at a first pressure for a first duration of time, and the second descum process is performed under a second process condition at a second pressure for a second duration of time, wherein the first pressure is different from the second pressure, and the first duration of time is different from the second duration of time. In an embodiment, the second pressure is lower than the first pressure, and the second duration of time is longer than the first duration of time. In an embodiment, the second pressure is between about 30% and about 70% of the first pressure, and wherein the second duration of time is between about one time and about five times of the first duration of time. In an embodiment, the first dielectric layer and the second dielectric layer are formed of a same polymer material. In an embodiment, the first descum process results in a first surface roughness parameter Rq for an upper surface of the first dielectric layer distal from the molding material, wherein the second descum process results in a second surface roughness parameter Rq for an upper surface of the second dielectric layer distal from the molding material, wherein the second surface roughness parameter Rq is larger than the first surface roughness parameter Rq. In an embodiment, forming the first RDL comprises forming an electrically conductive material in the first plurality of openings and on the first dielectric layer, wherein forming the second RDL comprises forming the electrically conductive material in the second plurality of openings and on the second dielectric layer. In an embodiment, the electrically conductive material on the first dielectric layer is formed to have a first thickness, and the electrically conductive material on the second dielectric layer is formed to have a second thickness larger than the first thickness. In an embodiment, forming the RDS further comprises: after performing the first descum process and before forming the first RDL, conformally forming a first seed layer in the first plurality of openings and on the first dielectric layer, wherein forming the first RDL comprises forming the electrically conductive material on the first seed layer; and after performing the second descum process and before forming the second RDL, conformally forming a second seed layer in the second plurality of openings and on the second dielectric layer, wherein forming the second RDL comprises forming the electrically conductive material on the second seed layer, wherein the first seed layer and the second seed layer are formed of a same material, wherein a second reflectivity of the second seed layer is lower than a first reflectivity of the first seed layer. In an embodiment, the first reflectivity is about 45%, and the second reflectivity is about 15%. In an embodiment, the second dielectric layer is deposited before the first dielectric layer such that the second dielectric layer is between the molding material and the first dielectric layer. In an embodiment, the second dielectric layer is deposited after the first dielectric layer such that the first dielectric layer is between the molding material and the second dielectric layer.

In accordance with an embodiment, a method of forming a semiconductor package includes: forming a molding material around a die; forming a first dielectric layer over the molding material using a polymer material; patterning the first dielectric layer to form a first plurality of openings in the first dielectric layer; after patterning the first dielectric layer, performing a first descum process, wherein the first descum process is a first plasma process performed at a first pressure for a first duration of time; after performing the first descum process, forming an electrically conductive material in the first plurality of openings and over an upper surface of the first dielectric layer to form a first redistribution layer (RDL); forming a second dielectric layer over the first dielectric layer using the polymer material; patterning the second dielectric layer to form a second plurality of openings in the second dielectric layer; after patterning the second dielectric layer, performing a second descum process, wherein the second descum process is a second plasma process performed at a second pressure for a second duration of time, wherein the second pressure is different from the first pressure, and the second duration of time is different from the first duration of time; and after performing the second descum process, forming the electrically conductive material in the second plurality of openings and over an upper surface of the second dielectric layer to form a second RDL. In an embodiment, the second pressure is lower than the first pressure, and the second duration of time is longer than the first duration of time. In an embodiment, the second pressure is between about 30% and about 70% of the first pressure, and the second duration of time is between about one time and about five times the first duration of time. In an embodiment, the first descum process results in a first surface roughness for the upper surface of the first dielectric layer, and the second descum process results in a second surface roughness for the upper surface of the second dielectric layer, wherein the second surface roughness is higher than the first surface roughness. In an embodiment, the method further comprises: after performing the first descum process and before forming the electrically conductive material in the first plurality of openings, forming a first seed layer in the first plurality of openings and over the upper surface of the first dielectric layer, wherein the first seed layer has a first reflectivity; and after performing the second descum process and before forming the electrically conductive material in the second plurality of openings, forming a second seed layer in the second plurality of openings and over the upper surface of the second dielectric layer, wherein the second seed layer has a second reflectivity different from the first reflectivity.

In accordance with an embodiment, a semiconductor package includes: a die; a molding material round the die; and a redistribution structure (RDS) at a first side of the molding material and electrically coupled to the die, the RDS comprising: a first dielectric layer contacting and extending along the first side of the molding material, wherein a first surface of the first dielectric layer distal from the molding material has a first surface roughness; a first redistribution layer (RDL) along the first surface of the first dielectric layer; a second dielectric layer along the first surface of the first dielectric layer and the first RDL, wherein a second surface of the second dielectric layer distal from the molding material has a second surface roughness higher than the first surface roughness; and a second RDL along the second surface of the second dielectric layer. In an embodiment, the first RDL comprises a first conductive line extending along the first surface of the first dielectric layer, wherein the second RDL comprises a second conductive line extending along the second surface of the second dielectric layer, wherein a first thickness of the first conductive line is smaller than a second thickness of the second conductive line. In an embodiment, the semiconductor package further comprises a via laterally spaced from the die and embedded in the molding material, wherein the via is electrically coupled to the RDS.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of forming a semiconductor package, the method comprising:
surrounding a die with a molding material; and
forming a redistribution structure (RDS) over the molding material and electrically coupled to the die, comprising:
depositing a first dielectric layer over the molding material;
patterning the first dielectric layer to form a first plurality of openings in the first dielectric layer;
performing a first descum process to clean the first plurality of openings;
after performing the first descum process, forming a first redistribution layer (RDL) on the first dielectric layer;
depositing a second dielectric layer over the molding material;
patterning the second dielectric layer to form a second plurality of openings in the second dielectric layer;
performing a second descum process to clean the second plurality of openings, wherein the first descum process and the second descum process are performed under different process conditions; and
after performing the second descum process, forming a second RDL on the second dielectric layer.

2. The method of claim 1, wherein the first descum process is performed under a first process condition at a first pressure for a first duration of time, and the second descum process is performed under a second process condition at a second pressure for a second duration of time, wherein the first pressure is different from the second pressure, and the first duration of time is different from the second duration of time.

3. The method of claim 2, wherein the second pressure is lower than the first pressure, and the second duration of time is longer than the first duration of time.

4. The method of claim 3, wherein the second pressure is between about 30% and about 70% of the first pressure, and wherein the second duration of time is between about one time and about five times of the first duration of time.

5. The method of claim 4, wherein the first dielectric layer and the second dielectric layer are formed of a same polymer material.

6. The method of claim 3, wherein the first descum process results in a first surface roughness parameter Rq for an upper surface of the first dielectric layer distal from the molding material, wherein the second descum process results in a second surface roughness parameter Rq for an upper surface of the second dielectric layer distal from the molding material, wherein the second surface roughness parameter Rq is larger than the first surface roughness parameter Rq.

7. The method of claim 3, wherein forming the first RDL comprises forming an electrically conductive material in the first plurality of openings and on the first dielectric layer, wherein forming the second RDL comprises forming the electrically conductive material in the second plurality of openings and on the second dielectric layer.

8. The method of claim 7, wherein the electrically conductive material on the first dielectric layer is formed to have a first thickness, and the electrically conductive material on the second dielectric layer is formed to have a second thickness larger than the first thickness.

9. The method of claim 7, wherein forming the RDS further comprises:
after performing the first descum process and before forming the first RDL, conformally forming a first seed layer in the first plurality of openings and on the first dielectric layer, wherein forming the first RDL comprises forming the electrically conductive material on the first seed layer; and
after performing the second descum process and before forming the second RDL, conformally forming a second seed layer in the second plurality of openings and on the second dielectric layer, wherein forming the second RDL comprises forming the electrically conductive material on the second seed layer, wherein the first seed layer and the second seed layer are formed of a same material, wherein a second reflectivity of the second seed layer is lower than a first reflectivity of the first seed layer.

10. The method of claim 9, wherein the first reflectivity is about 45%, and the second reflectivity is about 15%.

11. The method of claim 3, wherein the second dielectric layer is deposited before the first dielectric layer such that the second dielectric layer is between the molding material and the first dielectric layer.

12. The method of claim 3, wherein the second dielectric layer is deposited after the first dielectric layer such that the first dielectric layer is between the molding material and the second dielectric layer.

13. A method of forming a semiconductor package, the method comprising:
forming a molding material around a die;
forming a first dielectric layer over the molding material using a polymer material;
patterning the first dielectric layer to form a first plurality of openings in the first dielectric layer;
after patterning the first dielectric layer, performing a first descum process, wherein the first descum process is a first plasma process performed at a first pressure for a first duration of time;
after performing the first descum process, forming an electrically conductive material in the first plurality of openings and over an upper surface of the first dielectric layer to form a first redistribution layer (RDL);
forming a second dielectric layer over the first dielectric layer using the polymer material;
patterning the second dielectric layer to form a second plurality of openings in the second dielectric layer;
after patterning the second dielectric layer, performing a second descum process, wherein the second descum process is a second plasma process performed at a second pressure for a second duration of time, wherein the second pressure is different from the first pressure, and the second duration of time is different from the first duration of time; and
after performing the second descum process, forming the electrically conductive material in the second plurality of openings and over an upper surface of the second dielectric layer to form a second RDL.

14. The method of claim 13, wherein the second pressure is lower than the first pressure, and the second duration of time is longer than the first duration of time.

15. The method of claim 14, wherein the second pressure is between about 30% and about 70% of the first pressure, and the second duration of time is between about one time and about five times the first duration of time.

16. The method of claim 14, wherein the first descum process results in a first surface roughness for the upper surface of the first dielectric layer, and the second descum process results in a second surface roughness for the upper surface of the second dielectric layer, wherein the second surface roughness is higher than the first surface roughness.

17. The method of claim 13, further comprising:
after performing the first descum process and before forming the electrically conductive material in the first plurality of openings, forming a first seed layer in the first plurality of openings and over the upper surface of the first dielectric layer, wherein the first seed layer has a first reflectivity; and
after performing the second descum process and before forming the electrically conductive material in the second plurality of openings, forming a second seed layer in the second plurality of openings and over the upper surface of the second dielectric layer, wherein the second seed layer has a second reflectivity different from the first reflectivity.

18. A semiconductor package comprising:
a die;
a molding material round the die; and
a redistribution structure (RDS) at a first side of the molding material and electrically coupled to the die, the RDS comprising:
a first dielectric layer contacting and extending along the first side of the molding material, wherein a first surface of the first dielectric layer distal from the molding material has a first surface roughness;
a first redistribution layer (RDL) along the first surface of the first dielectric layer;
a second dielectric layer along the first surface of the first dielectric layer and the first RDL, wherein a second surface of the second dielectric layer distal from the molding material has a second surface roughness higher than the first surface roughness; and
a second RDL along the second surface of the second dielectric layer.

19. The semiconductor package of claim 18, wherein the first RDL comprises a first conductive line extending along the first surface of the first dielectric layer, wherein the second RDL comprises a second conductive line extending along the second surface of the second dielectric layer, wherein a first thickness of the first conductive line is smaller than a second thickness of the second conductive line.

20. The semiconductor package of claim 18, further comprising a via laterally spaced from the die and embedded in the molding material, wherein the via is electrically coupled to the RDS.
